(19) United States
(12) Patent Application Publication
(10) Pub. No.: US 2026/0231601 A1
(43) Pub. Date: Aug. 6, 2026

(54) LIGHT-EMITTING DIODE AND ELECTRONIC DEVICE INCLUDING THE SAME

(71) Applicant: Samsung Display Co., LTD., Yongin-si (KR)

(72) Inventors: DONGCHAN LEE, Yongin-si (KR); CHANGWOONG CHU, Yongin-si (KR); JIN-SOO JUNG, Yongin-si (KR); MINJU HAN, Yongin-si (KR); JAEWEON HUR, Yongin-si (KR)

(21) Appl. No.: 19/417,703

(22) Filed: Dec. 12, 2025

(30) Foreign Application Priority Data
Feb. 6, 2025 (KR) 10-2025-0015055

(51) Int. Cl. H10K 50/12; C07B 59/00; H10K 50/15; H10K 50/16; H10K 50/19; H10K 85/30; H10K 85/40; H10K 85/60; H10K 101/20; H10K 102/00

(52) U.S. Cl. CPC H10K 50/121; C07B 59/004; H10K 50/15; H10K 50/16; H10K 50/19; H10K 85/342; H10K 85/346; H10K 85/40; H10K 85/615; H10K 85/633; H10K 85/654; H10K 85/6572; H10K 85/6574; H10K 85/658; C07B 2200/05; H10K 2101/20; H10K 2102/351

(57) ABSTRACT

The present disclosure provides a light-emitting diode, and an electronic device. Particularly, the present disclosure provides a light-emitting diode with improved color purity and current efficiency and optimized lifespan and an electronic device including thereof, by the inclusion of stack units vertically laminated to form a plurality of layers, and including a plurality of light-emission layers on each layer. One or more light-emission layers among the plurality of light-emission layers in an uppermost stack unit among the laminated stack units are thermally activated delayed fluorescence light-emission layers configured to emit thermally activated delayed fluorescence, and at least one stack unit below the uppermost stack unit includes at least one of a phosphorescence light-emission layer or a fluorescence light-emission layer.

### CROSS-REFERENCE TO RELATED APPLICATION

The present application is based on claims priority to Korean Patent Application No. 10-2025-0015055, filed on Feb. 6, 2025, in the Korean Intellectual Property Office, and all the benefits accruing therefrom under 35 U.S.C. § 119, the content of which is incorporated herein in its entirety by reference.

### BACKGROUND

### 1. Field

One or more embodiments of the present disclosure relate to a light-emitting diode and an electronic device including the light-emitting diode.

### 2. Description of the Related Art

Recently, development of an organic light-emitting display device as an image display device has been highly active. An organic light-emitting display device includes an organic light-emitting diode including a first electrode, a light-emission layer, and a second electrode. The organic light-emitting display device is a display device of so-called self-light-emitting display device showing an image through light-emission of a light-emitting material including an organic compound by recombination of a hole and an electron injected from the first electrode and the second electrode in the light-emission layer.

In applications of an organic light-emitting diode, low operation voltage, high current efficiency and long lifespan of an organic light-emitting diode are desired. Accordingly, development of a material for an organic light-emitting diode for stable implementation of the above is constantly needed.

Particularly, in order to implement a highly efficient organic electroluminescent device, technologies about thermally activated delayed fluorescence light-emission using a phenomenon of triplet-triplet annihilation (TTA) in which singlet excitons are generated by collisions of triplet excitons are being developed. In addition, research is ongoing to develop a material for thermally activated delayed fluorescence (TADF) using the thermally activated delayed fluorescence phenomenon.

### SUMMARY

One or more aspects of embodiments of the present disclosure is to provide a light-emitting diode and an electronic device including the light-emitting diode.

It shall be clearly construed by those of ordinary skill in the art to which the present disclosure pertains that aspects of the present disclosure are not limited to the description, and other undescribed technical objects may be clearly understood from the description and appreciated by those of ordinary skill in the art to which the present disclosure pertains.

According to one or more embodiments of the present disclosure, a light-emitting diode according to one aspect of the present disclosure includes a first electrode, a second electrode arranged on the first electrode, and stack units arranged between the first electrode and the second electrode, vertically laminated to form a plurality of layers, and including a plurality of light-emission layers on each layer, wherein one or more light-emission layers among a plurality of light-emission layers in an uppermost stack unit among the laminated stack units are thermally activated delayed fluorescence (TADF) light-emission layers configured to emit thermally activated delayed fluorescence, and wherein at least one stack unit below the uppermost stack unit includes at least one of a phosphorescence light-emission layer or a fluorescence light-emission layer.

In one or more embodiments of the present disclosure, at least one of TADF light-emission layers in the uppermost stack unit may be a blue-light-emission layer.

In one or more embodiments of the present disclosure, two or more light-emission layers among the light-emission layers included in the uppermost stack unit may include a TADF light-emission layer.

In one or more embodiments of the present disclosure, the TADF light-emission layer may include a first host, a second host, a phosphorescence sensitizer, and a thermally activated delayed fluorescence emitter (TADF emitter).

In one or more embodiments of the present disclosure, the first host is a hole transport host, and the second host is an electron transport host.

In one or more embodiments of the present disclosure, the TADF light-emission layer may include the hole transport host in an amount of 30 to 80 parts by weight, the electron transport host in an amount of 20 to 60 parts by weight, the phosphorescence sensitizer in an amount of 10 to 20 parts by weight, and the thermally activated delayed fluorescence emitter in an amount of 0.5 to 3 parts by weight with respect to 100 parts by weight of the light-emission layer.

In one or more embodiments of the present disclosure, the hole transport host may include a compound represented by Formula H-1, a compound represented by Formula H-2, or a combination thereof. The electron hole transport host may include a compound represented by Formula ETH-1.

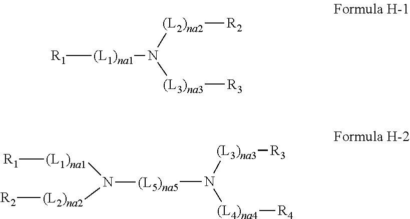

In Formula H-1 and Formula H-2, the L₁ through L₅ may independently be a direct linkage, a substituted or unsubstituted arylene group having 6 to 30 ring-forming carbons, or a substituted or unsubstituted heteroarylene group having 2 to 30 ring-forming carbons.

The na1 through na4 may each independently be an integer greater than or equal to 0 and smaller than or equal to 5, and the na5 may be an integer greater than or equal to 1 and smaller than or equal to 10.

The R₁ through R₄ may each independently be hydrogen, deuterium, a halogen, a substituted or unsubstituted alkyl group having 1 to 20 carbons, a cycloalkyl group having 3 to 10 ring-forming carbons, a substituted or unsubstituted heterocycloalkyl group having 1 to 10 ring-forming carbons, a substituted or unsubstituted cycloalkenyl group having 3 to 10 ring-forming carbons, a substituted or unsubstituted heterocycloalkenyl group having 1 to 10 ring-forming carbons, a substituted or unsubstituted aryl group having 6 to 60 ring-forming carbons, a substituted or unsubstituted aryloxy group having 6 to 60 carbons, a substituted or unsubstituted arylthio group having 6 to 60 carbons, or a substituted or unsubstituted heteroaryl group having 1 to 60 ring-forming carbons,

The R₁ and R₂ may be optionally connected to each other through a single bond, one or both of the R₁ and R₂ are connected to one or both of the R₃ and R₄ through a single bond.

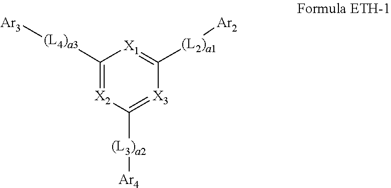

In Formula ETH-1, X₁ may be N or CR₉, X₂ may be N or CR₁₀, X₃ may be N or CR₁₁, and at least one of X₁ through X₃ may be N.

The R₉ through R₁₁ may each independently be hydrogen, deuterium, a halogen, a hydroxyl group, a cyano group, a nitro group, a substituted or unsubstituted alkyl group having 1 to 20 carbons, a substituted or unsubstituted alkenyl group having 2 to 20 carbons, a substituted or unsubstituted alkoxy group having 1 to 20 carbons, a substituted or unsubstituted alkynyl group having 2 to 20 carbons, a substituted or unsubstituted aryl group having 6 to 50 ring-forming carbons, and a substituted or unsubstituted heteroaryl group having 2 to 50 ring-forming carbons.

The L₂ through L₄ may each independently be a direct linkage, a substituted or unsubstituted arylene group having 6 to 30 ring-forming carbons, or a substituted or unsubstituted heteroarylene group having 2 to 30 ring-forming carbons.

The a1 through a3 may each independently be an integer greater than or equal to 0 and smaller than or equal to 10, and in the case that, i.e., when, the a1 through a3 each is an integer greater than or equal to 2, L₂ through L₄ may each independently be a substituted or unsubstituted arylene group having 6 to 30 ring-forming carbons, or a substituted or unsubstituted heteroarylene group having 2 to 30 ring-forming carbons.

The Ar₂ through Ar₄ may each independently be hydrogen, deuterium, a substituted or unsubstituted alkyl group having 1 to 20 carbons, a substituted or unsubstituted aryl group having 6 to 30 ring-forming carbons, and a substituted or unsubstituted heteroaryl group having 2 to 30 ring-forming carbons.

In one or more embodiments of the present disclosure, the phosphorescence sensitizer may include a compound represented by Formula P.

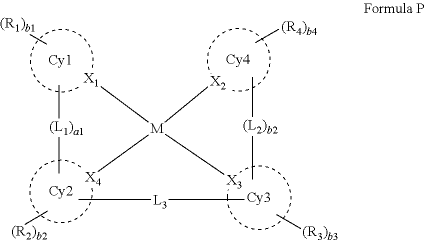

In Formula P, the M may be platinum (Pt), palladium (Pd), copper (Cu), silver (Ag), gold (Au), rhodium (Rh), iridium (Ir), ruthenium (Ru) or osmium (Os), and the X₁ through X₄ may each independently be a carbon (C) or a nitrogen (N). The rings Cy₁ through Cy₄ may each independently be a substituted or unsubstituted carbocyclic ring having 5 to 60 carbons, or a substituted or unsubstituted heterocyclic ring having 3 to 60 carbons.

The L₁ through L₃ may each independently be a direct linkage, *—O—*′, *—S—*′, *—C(R₅)(R₆)—*′, *—C(R₅)═*′, *═C(R₅)—*, *—C(R₅)═C(R₆)—*, *—C(═O)—*, *—C(═S)—*, *—C═C—*′, *B(R₅)—*′, *—N(R₅)—*′, *—P(R₅)—*′, *—Si(R₅)(R₆)—*′, *—P(R₅)(R₆)—*′ or *—Ge(R₅)(R₆)—*′. The a₁ and a₂ may each independently be an integer greater than or equal to 0 and smaller than or equal to 3. In the case that a₁ is 0, Cy₁ and Cy₂ may not be connected to each other through (L₁)a₁, and in the case that a1 is 2 or 3, a plurality of L₁ may be identical to or different from one another. In the case that a₂ is 0, Cy₃, and Cy₄ may not be connected to each other through (L₃)a2, and in the case that a2 is 2 or 3, a plurality of L₃ may be identical to or different from one another.

The R₁ through R₄ may each independently be hydrogen, deuterium, a halogen, a hydroxyl group, a cyano group, a nitro group, an alkyl group substituted or unsubstituted with at least one R₁₀ₐ and having 1 to 60 carbons, an alkenyl group substituted or unsubstituted with at least one R₁₀ₐ and having 2 to 60 carbons, an alkynyl group substituted or unsubstituted with at least one R₁₀ₐ and having 2 to 60 carbons, an alkoxy group substituted or unsubstituted with at least one R₁₀ₐ and having 1 to 60 carbons, a carbocyclic ring substituted or unsubstituted with at least one R₁₀ₐ and having 3 to 60 carbons, a heterocyclic ring substituted or unsubstituted with at least one R₁₀ₐ and having 3 to 60 carbons, an aryloxy group substituted or unsubstituted with at least one R₁₀ₐ and having 6 to 60 carbons, an arylthio group substituted or unsubstituted with at least one R₁₀ₐ and having 6 to 60 carbons, an arylalkyl group substituted or unsubstituted with at least one R₁₀ₐ and having 7 to 60 carbons, a heteroarylalkyl group substituted or unsubstituted with at least one R₁₀ₐ and having 3 to 60 carbons, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁) or —P(═O)(Q₁)(Q₂).

The b1 through b4 may each independently be an integer greater than or equal to 0 and smaller than or equal to 10. The R₁ through R₄ may optionally be connected to each other to form a structure selected from a carbocyclic ring having 3 to 20 carbons to one another and a heterocyclic ring having 1 to 20 carbons.

The R₁₀ₐ may each independently be deuterium, a halogen, a hydroxyl group, a cyano group, a nitro group, a carbocyclic ring having 3 to 60 carbons, a heterocyclic ring having 2 to 60 carbons, an aryloxy group having 6 to 60 carbons, an arylthio group having 6 to 60 carbons, an arylalkyl group having 7 to 60 carbons, a heteroarylalkyl group having 3 to 60 ring-forming carbons, a substituted or unsubstituted alkyl group having 1 to 60 carbons, alkenyl group having 2 to 60 carbons, alkynyl group having 2 to 60 carbons, alkoxy group having 1 to 60 carbons, carbocyclic ring having 3 to 60 carbons, heterocyclic ring having 2 to 60 ring-forming carbons, aryloxy group having 6 to 60 carbons, arylthio group having 6 to 60 carbons, arylalkyl group having 7 to 60 carbons, or heteroarylalkyl group having 3 to 60 carbons with —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), or —P(═O)(Q₁₁)(Q₁₂).

The Q₁ through Q₃ and Q₁₁ through Q₁₃ may each independently be a substituted or unsubstituted alkyl group having 1 to 60 carbons, an alkenyl group having 2 to 60 carbons, an alkynyl group having 2 to 60 carbons, an alkoxy group having 1 to 60 carbons, a carbocyclic ring having 3 to 60 ring-forming carbons, or a heterocyclic ring having 1 to 60 ring-forming carbons, wherein each of the foregoing is optionally substituted with hydrogen, deuterium, a halogen, a hydroxyl group, a cyano group, a nitro group, an alkyl group having 1 to 60 carbons, an alkoxy group having 1 to 60 carbons, a phenyl group, a biphenyl group, or a combination thereof.

In one or more embodiments of the present disclosure, the thermally activated delayed fluorescence emitter (TADF emitter) may include a compound represented by Formula F-a.

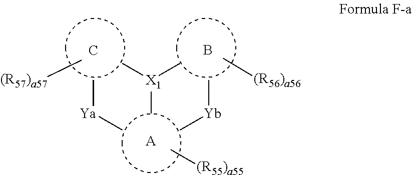

In Formula F-a, the ring A through ring C may each independently be a substituted or unsubstituted aromatic hydrocarbon ring having 6 to 60 ring-forming carbons or a substituted or unsubstituted aromatic heterocyclic ring having 2 to 60 ring-forming carbons.

The Yₐ and Yb may each independently be O, S, Se, CR₅₈R₅₉, NR₆₀, or SiR₆₁R₆₂.

The X₁ may be B, P or P—O, and the R₅₅ through R₆₂ may be each independently hydrogen, deuterium, a halogen, a cyano group, a nitro group, an amino group, a substituted or unsubstituted alkyl group having 1 to 30 carbons, a substituted or unsubstituted aryl group having 6 to 60 ring-forming carbons, a substituted or unsubstituted arylamino group, a substituted or unsubstituted cycloalkyl group having 3 to 30 ring-forming carbons, a substituted or unsubstituted heteroaryl group having 2 to 60 ring-forming carbons, a substituted or unsubstituted alkoxy group having 1 to 30 carbons, a substituted or unsubstituted aryloxy group having 6 to 30 carbons, a substituted or unsubstituted arylthio group having 6 to 30 carbons, a substituted or unsubstituted arylamine group having 5 to 30 carbons, a substituted or unsubstituted alkylsilyl group having 1 to 30 carbons, or a substituted or unsubstituted arylsilyl group having 5 to 30 carbons.

The a₅₅ through a₅₇ may each independently be an integer greater than or equal to 0 and smaller than or equal to 20.

In one or more embodiments of the present disclosure, the stack units may include a first stack unit, a second stack unit vertically laminated on the first stack unit, and wherein one or more electric charge generation layers are arranged between the first stack unit and the second stack unit.

In one or more embodiments of the present disclosure, a plurality of light-emission layers in the first stack unit may include at least one of a phosphorescence light-emission layer or a fluorescence light-emission layer, and wherein one or more light-emission layers among a plurality of light-emission layers in the second stack may be a TADF light-emission layer configured to emit thermally activated delayed fluorescence.

In one or more embodiments of the present disclosure, a thickness of the second stack unit may be thicker than a thickness of the first stack unit by 50 angstrom (Å) to 300 Å. In one or more embodiments of the present disclosure, λₘₐₓ of either a red (R) phosphorescence sensitizer or a green (G) phosphorescence sensitizer, or both of the red phosphorescence sensitizer and the green phosphorescence sensitizer in the second stack unit may satisfy Inequality 1 in relation with λₘₐₓ of a phosphorescence dopant included in the first stack unit.

### Inequality 1

λₘₐₓ of phosphorescence dopant of the first stack unit—λₘₐₓ of phosphorescence sensitizer of the second stack unit >1 nanometer (nm).

In one or more embodiments of the present disclosure, a triplet energy T1 (TADF) of the thermally activated delayed fluorescence emitter in the second stack unit and a triplet energy T1 (sensitizer) of each of a red phosphorescence sensitizer, a green (G) phosphorescence sensitizer, and a blue (B) phosphorescence sensitizer of the second unit may satisfy at least one of Inequality 2-1 through Inequality 2-3.

$$Δ {T}_{R} = T 1 ( Red sensitizer ) - T 1 ( Red TADF ) > 0.02 electronvolts ( eV ) \qquad Inequality 2 ‐ 1$$

$$Δ {T}_{G} = T 1 ( Green sensitizer ) - T 1 ( Green TADF ) > 0.02 eV \qquad Inequality 2 ‐ 2$$

$$Δ {T}_{B} = T 1 ( Blue sensitizer ) - T 1 ( Blue TADF ) > 0.02 eV . \qquad Inequality 2 ‐ 3$$

In one or more embodiments of the present disclosure, the phosphorescence light-emission layer and the fluorescence light-emission layer may include a plurality of light-emitting diodes and a phosphorescence or fluorescence dopant.

In one or more embodiments of the present disclosure, the phosphorescence or fluorescence dopant may be present in an amount of 0.01 to 30 parts by weight with respect to 100 parts by weight of the light-emission composition.

In one or more embodiments of the present disclosure, the stack unit may include a hole functional layer, a plurality of light-emission layers and an electron functional layer. The hole functional layer may include a hole transport layer, a hole injection layer, a light-emission auxiliary layer, or a combination thereof, and the electron functional layer may include an electron transport layer, an electron injection layer, a barrier film layer, a buffer layer, or a combination thereof.

In one more embodiments of the present disclosure, the light-emission auxiliary layer may be included in blue light-emission layer.

An electronic device according to another aspect of the present disclosure may include a light-emitting diode including a first electrode, a second electrode arranged on the first electrode, and stack units arranged between the first electrode and the second electrode, vertically laminated to form a plurality of layers, and including a plurality of light-emission layers on each layer, wherein one or more light-emission layers among a plurality of light-emission layers in at least an uppermost stack unit among the laminated stack units are thermally activated delayed fluorescence (TADF) light-emission layers configured to emit thermally activated delayed fluorescence, and wherein at least one stack unit below the uppermost stack unit includes at least one of a phosphorescence light-emission layer or a fluorescence light-emission layer.

In one or more embodiments of the present disclosure, the electronic device may include a display device, a processor configured to control the display device, a memory configured to store data necessary for operation of the display device or the processor, and a power module configured to generate or supply power.

A light-emitting diode according to one or more embodiments may have improved color purity and current efficiency along with an optimized lifespan.

An electronic device according to one or more embodiments may have improved current efficiency and an optimized lifespan.

However, effects of the present disclosure are not limited to the above effects but may be variously extended in a scope without departing from the spirit and scope of the present disclosure.

### BRIEF DESCRIPTION OF THE DRAWINGS

The accompanying drawings are included to provide a further understanding of the present disclosure and are incorporated in and constitute a part of this disclosure. The drawings illustrate embodiments of the present disclosure and, together with the description, serve to explain principles of the disclosure. These and/or other features will become apparent and more readily appreciated from the following description of one or more embodiments, taken in conjunction with the accompanying drawings, in which:

FIG. 1 is a cross-sectional view schematically illustrating a conventional tandem light-emitting diode;

FIG. 2 is a cross-sectional view schematically illustrating a tandem light-emitting diode;

FIG. 3 is an illustration schematically showing a light-emission mechanism of a TADF light-emission layer EML configuration according to one or more embodiments of the present disclosure;

FIG. 4 is a plan view illustrating a display device according to one or more embodiments of the present disclosure;

FIG. 5 is a block diagram of an electronic device according to one or more embodiments of the present disclosure; and

FIG. 6 through FIG. 8 are schematic diagrams of electronic devices according to various embodiments.

### DETAILED DESCRIPTION

References will now be made in more detail to certain embodiments, of which examples are illustrated in the accompanying drawings, where like reference numerals refer to like elements throughout the disclosure, and duplicative descriptions thereof may not be provided for conciseness. The presented embodiments may have a variety of forms and permutations, but the present disclosure shall by no means be construed as being limited to the described embodiments. Rather, the present disclosure shall be construed to encompass all form, permutations, equivalents, and substitutes covered by the technical ideas and scope of the present disclosure. Accordingly, one or more embodiments are merely described, by referring to the drawings, to explain features of the present disclosure and to convey the scope of the disclosure to those skilled in the art.

Unless otherwise defined, all technical terms and scientific terms used herein have the same meaning as how they are generally understood by those of ordinary skill in the art to which the present disclosure pertains. However, if (e.g., when) the meanings do not match, a description, including a definition, of the present disclosure takes precedence.

Terms such as “first” and “second” may be used in describing one or more suitable elements, but the elements shall not be restricted to the terms. The terms may be used only to distinguish one element from the other. For instance, the first element may be named the second element, and vice versa, without departing the scope of the present disclosure. Unless clearly used otherwise, any expressions in a singular form may include a meaning of a plural form. For example, the singular forms “a,” “an,” “one,” and “the” are intended to include the plural forms as well, unless the context clearly indicates otherwise. The term “and/or” or “or” as used herein shall include the combination of a plurality of listed items or any of the plurality of listed items. Further, the utilization of “may” when describing embodiments of the present disclosure refers to “one or more embodiments of the present disclosure.”

When an element is described to be “on”, “placed on”, “arranged on”, “connected to”, or “coupled to” another element, it shall be construed as being on, placed on, arranged on, connected to, or coupled to the other element directly but also as possibly having another element arranged between the element and the other element. In contrast, if (e.g., when) one element is described to be “directly on”, “directly placed on”, “directly arranged on”, “directly connected to” or “directly coupled to” another element, it shall be construed that there is no other element arranged between the element and the another element.

An expression such as “comprise(s)/comprising”, “include(s)/including”, or “has (have)/having” is intended to designate a characteristic, a number, a step (e.g., act or task), an operation, an element, a part, and/or one or more (e.g., any suitable) combinations thereof, and shall not be construed to preclude any possibility of presence or addition of one or more other characteristics, numbers, steps, operations, elements, parts, and/or one or more (e.g., any suitable) combinations thereof. Additionally, the terms “comprise(s)/comprising,” “include(s)/including,” “has (have)/having,” or other similar terms include or support the terms “consisting of” and “consisting essentially of,” indicating the presence of stated features, integers, steps, operations, elements, components, and/or groups, without or essentially without the presence of other features, integers, steps, operations, elements, components, and/or groups thereof.

When a component is described to be arranged “on (or below)” an element or “above (or below)” an element, it shall be construed not only as being arranged directly on (or below) the element but also as possibly having another element arranged between the component and the element.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Any reference to “and/or” shall be construed to include one or more combinations that can be defined by relevant elements. A size and a thickness of each configuration illustrated in a drawing is shown as an example for convenience, and embodiments of the present disclosure are not limited thereto.

As used herein, [symbol] and [symbol] may each refer to a binding site.

As used herein, a direct linkage may refer to a chemical bond, such as a single bond.

As used herein, examples of halogens may include fluorine, chlorine, bromine, and iodine.

As used herein, a “substituted or unsubstituted” group may be a group unsubstituted or substituted with at least one substituent selected from among a group containing deuterium, halogens, a nitro group, an amine group, a cyano group, a silyl group, an oxy group, a thio group, a sulfinyl group, a sulfonyl group, a carbonyl group, a boron group, an alkyl group, an alkenyl group, an alkynyl group, an alkoxy group, a phosphine sulfide group, a phosphine oxide group, a hydrocarbon ring group, an aryl group, and a heterocyclic group. In addition, each of the substituents presented as examples above may be substituted or unsubstituted. For example, a biphenyl group may be interpreted as an aryl or as a phenyl group substituted with a phenyl group.

As used herein, the phrase “forming a ring by combining with an adjacent group” and/or the like may refer to forming a substituted or unsubstituted hydrocarbon ring or a substituted or unsubstituted heterocycle by combining with an adjacent group. The hydrocarbon ring includes an aliphatic hydrocarbon ring and/or an aromatic hydrocarbon ring. The heterocycle includes an aliphatic heterocycle and/or an aromatic heterocycle. The carbon ring and the heterocycle may each be a monocycle or a polycycle. In addition, the formed ring may be combined with another ring to form a spiro structure.

As used herein, a fluorenyl group may be substituted, and two substituents may be combined to form a spiro structure with the fluorenyl group.

As used herein, the phrase “an adjacent group” may refer to a substitute connected to an atom which is directly connected to another atom substituted with another substituent; a substituent connected to an atom which is substituted with another substituent; or a substituent sterically positioned at the nearest position to another substituent. For example, two methyl groups in 1,2-dimethylbenzene may be interpreted as an “adjacent group” to each other.

As used herein, an alkyl group may have a linear chain or a branched chain. The number of carbons in the alkyl group may be 1 to 30, 1 to 20, or 1 to 10. Non-limiting examples thereof may include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 3,3-dimethylbutyl, 2-ethylbutyl, heptyl, n-heptyl, 1-methylhexyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylhexyl, 4-methylhexyl, and 5-methylhexyl.

As used herein, a cycloalkyl group may refer to a cyclic alkyl group. The number of carbons in the cycloalkyl group may be 3 to 50, 3 to 30, or 3 to 10. Non-limiting examples of the cycloalkyl group may include cyclopropyl, cyclobutyl, cyclopentyl, cyclohexyl, 4-methylcyclohexyl, 4-t-butylcyclohexyl, cycloheptyl, cyclooctyl, cyclononyl, cyclodecyl, norbornyl, 1-adamantyl, 2-adamantyl, isobornyl, or bicycloheptyl, but the present disclosure is not limited thereto.

As used herein, an alkenyl group may refer to a hydrocarbon group including one or more carbon-carbon double bonds in the middle and/or at the terminal of an alkyl group having 2 or more carbons. An alkenyl group may have a linear chain or a branched chain. The number of carbons in the alkenyl group may be, but not limited to, 2 to 30, 2 to 20 or 2 to 10. Non-limiting examples of the alkenyl group may include 1-butenyl, 1-pentenyl, 1,3-butadienyl aryl, and styrenyl.

As used herein, an alkynyl group may refer to a hydrocarbon group including one or more carbon-carbon triple bonds in the middle and/or at the terminal of an alkyl group having 2 or more carbons. The number of carbons in the alkynyl group may be, but not limited to, 2 to 30, 2 to 20 or 2 to 10. Non-limiting examples of the alkynyl group may include ethynyl and propynyl.

As used herein, a carbocyclic refers to a monocyclic or polycyclic group having carbons only as ring-forming atoms and having 3 to 60 carbons. A carbocyclic having 3 to 60 carbons may include an aromatic carbocyclic group or a non-aromatic carbocyclic group. Particularly, the carbocyclic group having 3 to 60 carbons may include a non-aromatic carbocyclic group.

As used herein, a heterocyclic refers to a cyclic group having 1 to 60 carbons and further including a heteroatom as a ring-forming atom other than a carbon. A heteroatom may include one or more of B, O, N, P, Si, and S.

As used herein, a hydrocarbon ring may be a functional group or any substituent group derived from an aromatic hydrocarbon ring, or any functional group or any substituent group derived from an aromatic hydrocarbon ring, and include at least one heteroatom selected from B, O, N, P, Si, and S as an atom. In the case that two or more heteroatoms are included, the two or more heteroatoms may be identical to or different from one another.

As used herein, an aryl group refers to a functional group or a substituent derived from an aromatic hydrocarbon ring. The aryl group may be a monocyclic aryl or a polycyclic aryl. The aryl group may have 6 to 60, 6 to 30, 6 to 20, or 6 to 15 ring-forming carbons. Non-limiting examples of the aryl group may include a phenyl group, a fluorenyl group, an anthracenyl group, a naphthyl group, a terphenyl group, a biphenyl group, a sexiphenyl group, a triphenylenyl group, and a benzofluoranthenyl group.

As used herein, a heterocyclic group may refer to any functional group or substituent derived from a ring including at least one of B, O, N, P, Si, or S as a ring-forming heteroatom. The heterocyclic group may include an aliphatic heterocyclic group and/or an aromatic heterocyclic group. The aromatic heterocyclic group may be a heteroaryl group. The aliphatic heterocyclic and the aromatic heterocyclic may each be a monocyclic or a polycyclic.

As used herein, if (e.g., when) the heterocyclic group includes two or more heteroatoms, the two or more heteroatoms may be identical to or different from each other. The heterocyclic group may be a monocyclic heterocyclic or a polycyclic heterocyclic and interpreted as a concept including a heteroaryl group. The heterocyclic group may have 2 to 30, 2 to 20, or 2 to 10 ring-forming carbons.

As used herein, an aliphatic heterocyclic group may include at least one of B, O, N, P, Si, or S as a ring-forming heteroatom. The aliphatic heterocyclic group may have 2 to 30, 2 to 20, or 2 to 10 ring-forming carbons. Non-limiting examples of the aliphatic heterocyclic group may include a thiirane group, a pyrrolidine group, a piperidine group, a tetrahydrofuran group, and 1,4-dioxane group.

As used herein, a heteroaryl group may include at least one of B, O, N, P, Si, or S as a ring-forming atom. When the heteroaryl group includes two or more heteroatoms, the two or more heteroatoms may be identical to or different from each other. The heteroaryl group may be a monocyclic heterocyclic ring or a polycyclic heterocyclic ring. The heteroaryl group may have 2 to 60 ring-forming carbons, 2 to 30, 2 to 20, or 2 to 10 ring-forming carbons. Non-limiting examples may include a furan group, a pyrrole group, an imidazole group, a pyridine group, a pyrimidine group, a triazine group, a pyridazine group, a quinoline group, an isoquinoline group, a pyridopyrimidine group, a benzocarbazole group, a benzofuran group, and an oxazole group.

As used herein, the above description of the aryl group may be applied to an arylene group, except that the arylene group is a polyvalent group (e.g., a divalent group). The above description of the heteroaryl may be applied to a heteroarylene group, except that the heteroarylene group is a polyvalent group (e.g., a divalent group). A polyvalent group may refer to, but not limited to, a trivalent or quadrivalent group and be applied with the above description.

As used herein, a silyl group may include an alkyl silyl group and/or an aryl silyl group. Non-limiting examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, and a phenylsilyl group.

As used herein, a boryl group may include an alkyl boryl group and/or an aryl boryl group.

Non-limiting examples of the boryl group may include a dimethylboryl group, a diethylboryl group, a t-butylmethylboryl group, a diphenylboryl group, or a phenylboryl group.

As used herein, a thio group may include an alkyl thio group and/or an aryl thio group. A thio group may indicate a group in which a sulfur atom is bonded to an alkyl or an aryl group defined above. Non-limiting examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthiol group, and a naphthylthio group.

As used herein, an oxy group may indicate a group in which an oxygen atom is bonded to an alkyl or an aryl group defined above. The oxy group may include an alkoxy group and/or an aryl oxy group. An alkoxy group may be linear, branched, or cyclic. The number of carbon atoms in the alkoxy group is not particularly limited, but may be, for example, 1 to 20, or 1 to 10. Non-limiting examples of the oxy group may include a methoxy, an ethoxy, a n-propoxy, an isopropoxy, a butoxy, a pentyloxy, a hexyloxy, an octyloxy, a nonyloxy, a decyloxy, and a benzyloxy.

As used herein, a boron group may refer to a group in which a boron atom is bonded to an alkyl or an aryl group defined above. The boron group may include an alkyl boron group and/or an aryl boron group. Non-limiting examples of the boron group may include a dimethyboron group, a diethylboron group, a t-butylmethylboron group, a diphenylboron group, and a phenylboron group.

As used herein, the number of carbon atoms in an amine group is not particularly limited, but may be 1 to 30. The amine group may include an alkyl amine group and/or an aryl amine group. Non-limiting examples of the amine group may include a methylamine group, a dimethylamine group, a phenylamine group, a diphenylamine group, a naphthylamine group, a 9-methyl-anthracenylamine group, and a triphenylamine group.

As used herein, a plurality of groups that “are each independently” means that each of the groups may be the same or different as each other.

Hereinafter, certain example embodiments of the present disclosure will be described in more detail with reference to the accompanying drawings. In the description with reference to the drawings, like or corresponding elements will be assigned the same reference numerals, and redundant descriptions thereof will be omitted.

A light-emitting diode ED according to one aspect of the present disclosure includes a first electrode, a second electrode arranged on the first electrode, and stack units arranged between the first electrode and the second electrode, vertically laminated to form a plurality of layers, and including a plurality of light-emission layers EML on each layer, wherein one or more light-emission layers among a plurality of light-emission layers EML included in at least an uppermost stack unit among the laminated stack units are thermally activated delayed fluorescence (TADF) light-emission layers configured to emit thermally activated delayed fluorescence, and wherein at least one stack unit below the uppermost stack unit includes at least one of a phosphorescence light-emission layer or a fluorescence light-emission layer.

The first electrode EL1 is conductive (e.g., is a conductor). The first electrode EL1 may include a metal material, a metal alloy, or a conductive compound. The first electrode EL1 may be an anode or a cathode.

The first electrode EL1 may be a reflective electrode, a semi-transmissive electrode, or a transmissive electrode. If (e.g., when) the first electrode EL1 is a transmissive electrode, material(s) such as indium tin oxide (ITO), indium zinc oxide (IZO), zinc oxide (ZnO), indium tin zinc oxide (ITZO) may be included. If (e.g., when) the first electrode EL1 is a semi-transmissive electrode or a reflective electrode, the first electrode EL1 may include silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), LiF/Ca (lamination structure of lithium fluoride (LiF) and Ca), LiF/Al (lamination structure of LiF and Al), molybdenum (Mo), titanium (Ti), tungsten (W), and/or a (e.g., any suitable) combination and/or mixture thereof (e.g., a mixture of Ag and Mg)). In one or more embodiments, the first electrode EL1 may have a multilayer structure including a reflective film or a semi-transmissive film including one or more of the aforementioned materials and a transparent conductive film including ITO (indium tin oxide), IZO (indium zinc oxide), ZnO (zinc oxide), ITZO (indium tin zinc oxide), and/or the like. For example, in one or more embodiments, the first electrode EL1 may have a triple layer structure of ITO/Ag/ITO or a multiple layer structure of a triple layer structure of ITO/Al/ITO, but embodiments of the present disclosure are not limited to this configuration.

The second electrode EL2 may be provided on an electron functional layer EFL. The second electrode EL2 may be a common electrode. In one or more embodiments, the second electrode EL2 may be a cathode or an anode, but embodiments of the present disclosure are not limited thereto. For example, if (e.g., when) the first electrode EL1 is an anode, the second electrode EL2 may be a cathode, and when the first electrode EL1 is a cathode, the second electrode EL2 may be an anode. Here, an alloy, a metal, an electrically conductive compound having a low work function, or a combination thereof may be used as a material for the second electrode EL2.

The second electrode EL2 may include, but not limited to, lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or a combination thereof. The second electrode EL2 may be a transmissive electrode, a semi-transmissive electrode, or a reflective electrode.

In one or more embodiments, the second electrode EL2 may be connected to an auxiliary electrode. In the case that the second electrode EL2 is connected to the auxiliary electrode, a resistance of the second electrode EL2 may be decreased.

In one or more embodiments, the second electrode EL2 may have a single layer structure of a single layer or a multi-layer structure of a plurality of layers.

The stack units of the present disclosure may be arranged between the first electrode and the second electrode and laminated to form a plurality of layers, and include a plurality of light-emission layers EML on each layer.

At least one or more light-emission layers among a plurality of light-emission layers EML included in at least an uppermost stack unit among the laminated stack units are thermally activated delayed fluorescence (TADF) light-emission layers configured to emit thermally activated delayed fluorescence, and at least one stack unit below the uppermost stack unit includes at least one of a phosphorescence light-emission layer or a fluorescence light-emission layer.

As described above, a plurality of stack units may have a hybrid structure, and according to the configuration, in which one or more light-emission layers are TADF light-emission layers configured to emit thermally activated delayed fluorescence, a light-emitting diode of the present disclosure may have increased current efficiency, improved color purity, and optimized lifespan.

In one or more embodiments of the present disclosure, at least one TADF light-emission layer included in the uppermost stack unit may be blue light-emission layer. According to the above configuration, current efficiency may be improved by about 20% or more, about 30% or more, about 40% or more, or about 50% or more in comparison to a conventional light-emitting diode.

In one or more embodiments of the present disclosure, a light-emitting diode may include two or more TADF light-emission layers among light-emission layers included in the uppermost stack unit. According to the above configuration, current efficiency may be improved.

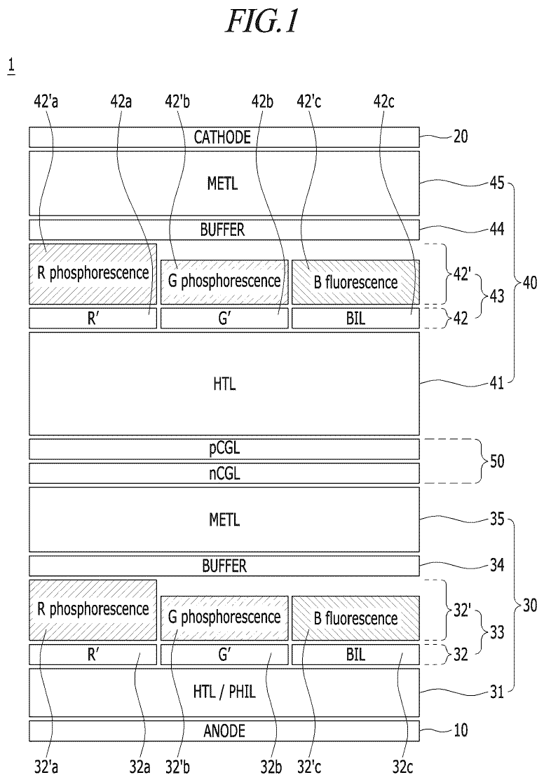

FIG. 1 shows a schematic cross-sectional view of a conventional tandem light-emitting diode. Referring to FIG. 1, a conventional light-emitting diode 1 may have a first stack unit 30 and a second stack unit 40 having the same structure as the first stack unit 30 laminated between a first electrode 10 and a second electrode 20 and having an electric charge generation layer 50 therebetween. For example, a light-emission layer 33 and 43 of a stack unit includes a red-light-emission layer, a green-light-emission layer, and a blue-light-emission layer. The red-light-emission layer may include a red-light-emitting unit 32a and 42a, and a red-light phosphorescence dopant 32′a and 42′a laminated on the red-light-emitting unit 32a and 42a, the green-light-emission layer may include a green-light-emitting unit 32b and 42b, and a green-light phosphorescence dopant 32′b and 42′b laminated on the green-light-emitting unit 32b and 42b, and the blue-light-emission layer may include a light-emitting unit and a blue-light fluorescence dopant 32′c and 42′c on a light-emission auxiliary layer 32c and 42c. A buffer layer 34 and 44, and an electron transport layer 35 and 45 may be laminated on the red-light phosphorescence dopant 32′a and 42′a, the green-light phosphorescence dopant 32′b and 42′b, and the blue-light fluorescence dopant 32′c and 42′c.

The conventionally available light-emitting diode 1 having a tandem structure has a limitation in increasing efficiency due to low quantum efficiency of fluorescence blue-light-emission layer and wide half-widths (FWHM) of phosphorescence red-light-emission layer and phosphorescence green-light-emission layer.

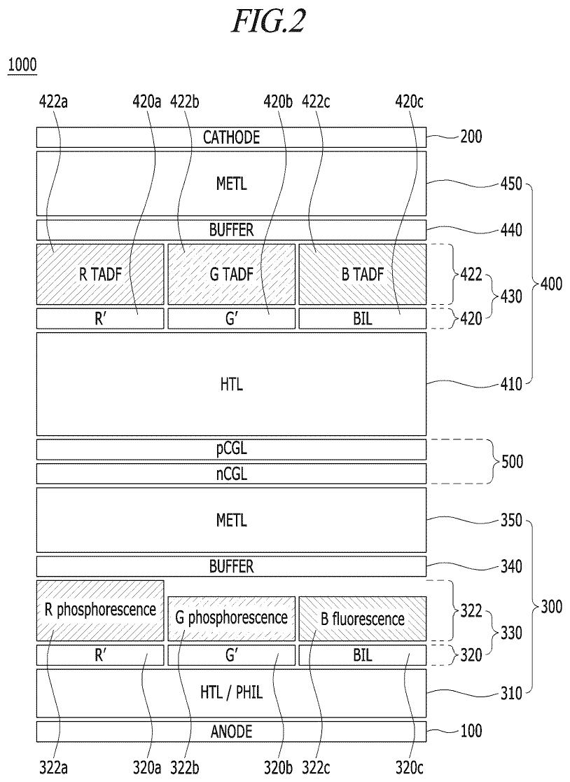

FIG. 2 shows a schematic cross-sectional view of a tandem light-emitting diode according to one or more embodiments of the present disclosure. Referring to FIG. 2, a tandem light-emitting diode 1000 according to one or more embodiments of the present disclosure may include, but not limited to, a first stack unit 300 and a second stack unit 400. A light-emitting diode 1000 of the tandem structure according to one or more embodiments of the present disclosure may have a first stack unit 300 and a second stack unit 400 having a different structure from the first stack unit 300 laminated between a first electrode 100 and a second electrode 200 and having an electric charge generation layer 500 therebetween. Also, the tandem light-emitting diode 1000 according to another embodiment of the present disclosure may have a hybrid stack unit structure.

The first stack unit 300 and the second stack unit 400 may include a hole transport layer 310 or 410, a light-emission layer 330 or 430, a buffer layer 340 or 440, and an electron transport layer 350 or 450. Particularly, the light-emission layer 330 may further include a light-emitting unit 320 (e.g., 320a and 320b), dopant 322 (e.g., 322a, 322b, and 322c), and a light-emission auxiliary layer 320c included in the light-emitting unit. The light-emission layer 330 in the first stack unit and/or the light-emission layer 430 in the second stack unit may include one or more types of a red-light-emission layer, a green-light-emission layer, and a blue-light-emission layer. It is illustrated that the light-emission layer 330 or 430 shown in FIG. 2 includes all red-light-emission layer, green-light-emission layer, and blue-light-emission layer, but the present disclosure is not limited thereto. The light-emission layer 330 or 430 shown in FIG. 2 may include one or more types of a red-light-emission layer, a green-light-emission layer, and a blue-light-emission layer.

The light-emission layer 430 of the second stack unit may include one or more types of a host, a dopant, and a TADF emitter. The host, the dopant, and the TADF emitter may be laminated on each other, or mixed in a certain ratio to be simultaneously laminated to form a single layer.

The light-emission layer 430 of the second stack unit may include a light-emitting unit 420 and a dopant 422 (e.g., 422a and 422b) including a TADF emitter laminated on the light-emitting unit 420 (e.g., 420a, 420b, and 420c). In addition, the blue-light-emission layer may further include, but not limited to, a light-emission auxiliary layer 420c on the light-emitting unit. A buffer layer 440, an electron transport layer 450 and a second electrode may be laminated on the dopant 422.

Although FIG. 2 illustrates a tandem structure, the light-emission layer may be formed of a plurality of layers, and a light-emission layer 430 of at least an uppermost stack unit, for example a second stack unit 400 shown in FIG. 2, among the stack units vertically stacked to form a plurality of layers may include a plurality of light-emission layers (R, G or B light-emission layer), and one or more light-emission layers among the plurality of light-emission layers is a TADF (Thermally Activated Delayed Fluorescence) light-emission layer configured to emit thermally activated delayed fluorescence.

The hole transport layer 310 or 410 may be configured to facilitate movement of a hole from the first electrode 100 to a light-emission unit layer 320 or 420, and the electron transport layer 350 or 450 may be configured to facilitate movement of an electron from the second electrode 200 to a light-emission unit layer 320 or 420.

A hole transport layer, a light-emission auxiliary layer and an electron transport layer are included in FIG. 2, but FIG. 2 is illustrated merely as an example. Embodiments of the present disclosure is not limited thereto. For example, a light-emitting diode of the present disclosure may further include at least one of a hole injection layer and an electron blocking layer to facilitate movement of a hole in the light-emitting diode.

A first stack unit 300 of a light-emitting diode according to the present disclosure may minimize a risk of decrease in a lifespan while increasing current efficiency, but the present disclosure is not limited thereto.

In one or more embodiments of the present disclosure, the TADF light-emission layer may include a first host, a second host, a phosphorescence sensitizer, and a thermally activated delayed fluorescence emitter (TADF emitter).

The TADF light-emission layer may refer to a light-emission layer including a thermally activated delayed fluorescence compound. The thermally activated delayed fluorescence compound may be selected from any compounds configured to emit thermally activated delayed fluorescence through a thermally activated delayed fluorescence emission mechanism.

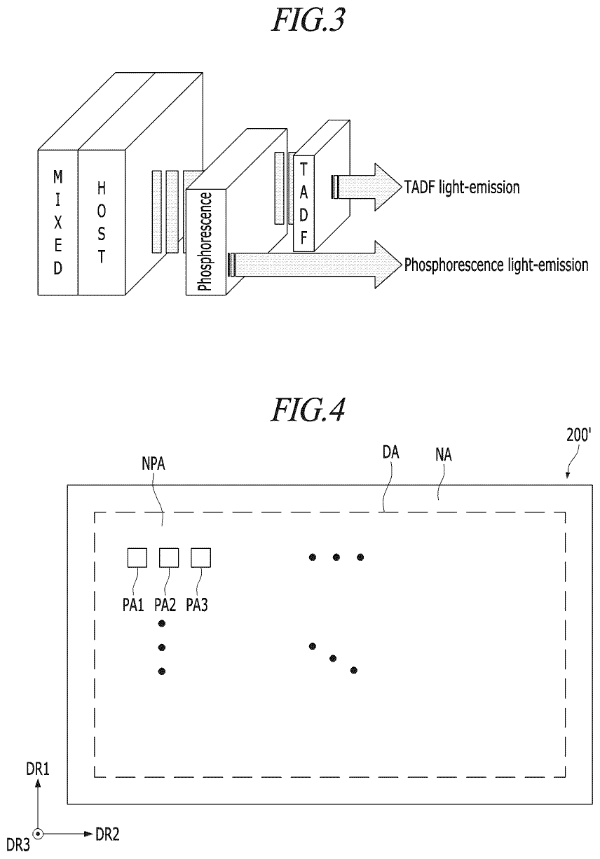

FIG. 3 is an illustration schematically showing a light-emission mechanism of a TADF light-emission layer EML configuration according to one or more embodiments of the present disclosure. Referring to FIG. 3, current efficiency of phosphorescence light-emission through phosphorescence sensitizer via two hosts is superior, and 4-component-based TADF light-emission through a phosphorescence sensitizer and a thermally activated delayed fluorescence emitter may have a synergic effect to have not only excellent current efficiency, but also excellent lifespan.

In one or more embodiments of the present disclosure, the first host may be a hole transport host, the second host is the electron transport host, but the present disclosure is not limited thereto.

A hole and an electron transferred through the hole transport host and the electron transport host may be converted to an exciton to be transferred to a dopant in a light-emission layer.

In one or more embodiments of the present disclosure, light-emission layers EML of two or more types in the second stack unit may include a hole transport host in an amount of 30 to 80 parts by weight, an electron transport host in an amount of 20 to 60 parts by weight, a sensitizer in an amount of 10 to 20 parts by weight, and a thermally activated delayed fluorescence emitter in an amount of 0.5 to 3 parts by weight with respect to 100 parts by weight of a light-emission layer composition.

In the case that an amount of the hole transport host is out of a range of 30 to 80 parts by weight with respect to 100 parts by weight of the light-emission layer composition or in the case that an amount of the electron transport host is out of a range of 20 to 60 parts by weight with respect to 100 parts by weight of light-emission layer composition, it may be difficult to efficiently transfer generation energy of a hole or an electron received by the host. The hole transport host may be included in an amount of 35 to 75 parts by weight with respect to 100 parts by weight of the light-emission layer composition, and the electron transport host may be included in an amount of 25 to 55 parts by weight with respect to 100% of the light-emission layer composition, but the present disclosure is not limited thereto.

In the case that an amount of the sensitizer is out of a range of 10 to 20 parts by weight with respect to 100 parts by weight of the light-emission layer composition, transfer of generated energy to the thermally activated delayed fluorescence emitter is reduced, and it may be difficult to have lifetime reduction effects of a triplet by the sensitizer. An amount of the sensitizer may be 13 to 18 parts by weight with respect to 100 parts by weight of the light-emission layer composition, but the present disclosure is not limited thereto.

In the case that an amount of the thermally activated delayed fluorescence emitter is out of a range of 0.5 to 3 parts by weight with respect to 100 parts by weight of light-emission layer composition, it is difficult for the light-emission layer to have an improved light-emission property. An amount of the thermally activated delayed fluorescence emitter may be 0.7 parts by weight to 2.8 parts by weight with respect to 100 parts by weight of the light-emission layer composition, but the present disclosure is not limited thereto.

The light-emission layer EML may include a compound represented by Formula H-1, a compound by Formula H-2, or a combination thereof as a hole transport host (HT host), but the present disclosure is not limited thereto.

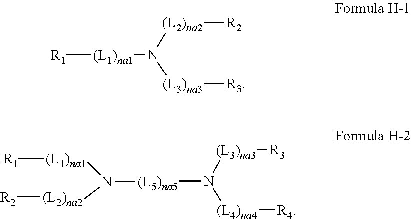

In Formula H-1 and Formula H-2, the L₁ through L₅ may each independently be direct linkage, a substituted or unsubstituted arylene group having 6 to 30 ring-forming carbons, or a substituted or unsubstituted heteroarylene group having 2 to 30 ring-forming carbons. The na₁ through na₄ may each independently be an integer greater than or equal to 0 and smaller than or equal to 5, and the na₅ may be an integer greater than or equal to 1 and smaller than or equal to 10.

In Formula H-1 and Formula H-2, the R₁ through R₄ may each independently be among hydrogen, deuterium, a halogen, a substituted or unsubstituted alkyl group having 1 to 20 carbons, a cycloalkyl group having 3 to 10 ring-forming carbons, a substituted or unsubstituted heterocycloalkyl group having 1 to 10 ring-forming carbons, a substituted or unsubstituted cycloalkenyl group having 3 to 10 ring-forming carbons, a substituted or unsubstituted heterocycloalkenyl group having 1 to 10 ring-forming carbons, a substituted or unsubstituted aryl group having 6 to 60 ring-forming carbons, a substituted or unsubstituted aryloxy group having 6 to 60 carbons, a substituted or unsubstituted arylthio group having 6 to 60 carbons, and a substituted or unsubstituted heteroaryl group having 1 to 60 ring-forming carbons. For example, R₁ through R₄ may each independently be, but not limited to, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, a fluoranthenyl group, a triphenylenyl group, a pyrenyl group, a perylenyl group, a pentaphenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, or a pyridinyl group.

In Formula H-1 and Formula H-2, R₁ and R₂ may be optionally connected to each other through a single bond, and/or connected to R₃ and R₄ through a single bond.

In one or more embodiments, the compound represented by Formula H-1 or Formula H-2 may be a carbazole-based compound including a substituted or unsubstituted carbazole group to at least one of R₁ through R₄, or may be a fluorenyl-based compound including a substituted or unsubstituted fluorenyl group to at least one of R₁ through R₄.

The compound represented by Formula H-1 or Formula H-2 may be represented by HT-1 through HT-16, which are compounds included in Compound Group 1, but the present disclosure is not limited thereto.

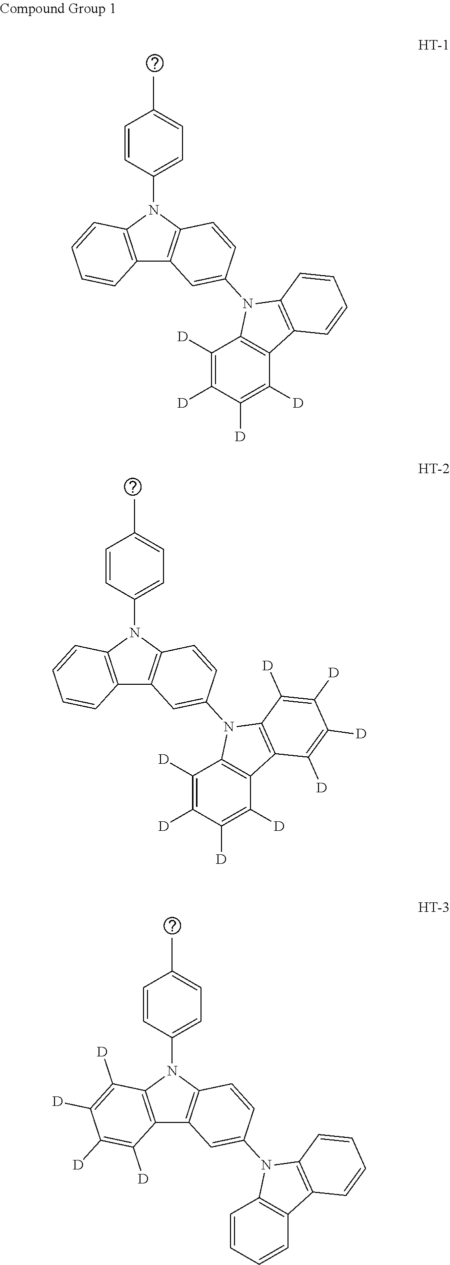 [SMILES: [2H]c1c([2H])c([2H])c2c(c1[2H])c1ccccc1n2-c1ccc2c(c1)c1ccccc1n2-c1ccc(C)cc1 ; [2H]c1c([2H])c([2H])c2c(c1[2H])c1c([2H])c([2H])c([2H])c([2H])c1n2-c1ccc2c(c1)c1ccccc1n2-c1ccc(C)cc1 ; [2H]c1c([2H])c([2H])c2c(c1[2H])c1cc(-n3c4ccccc4c4ccccc43)ccc1n2-c1ccc(C)cc1]

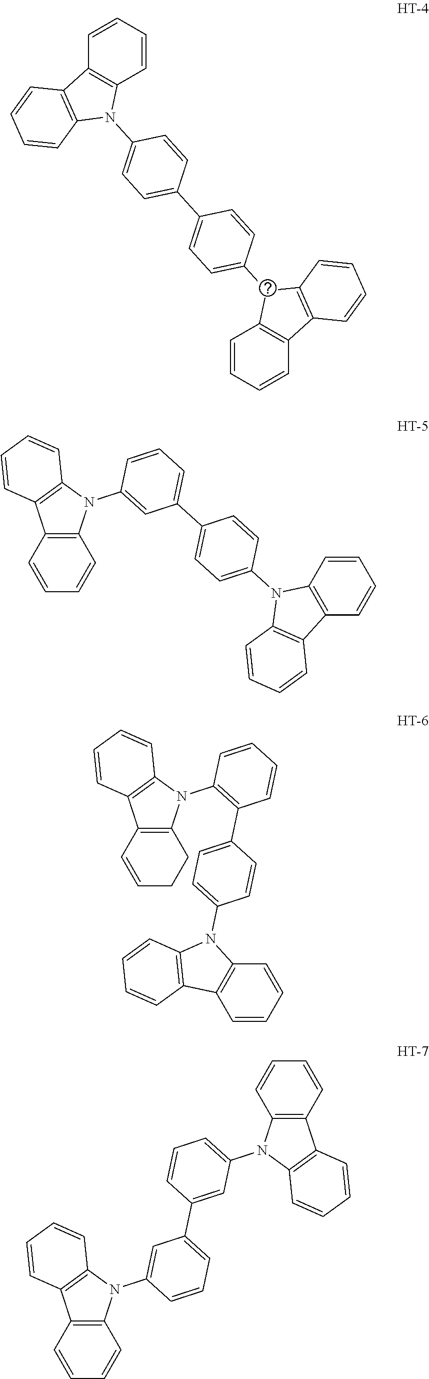

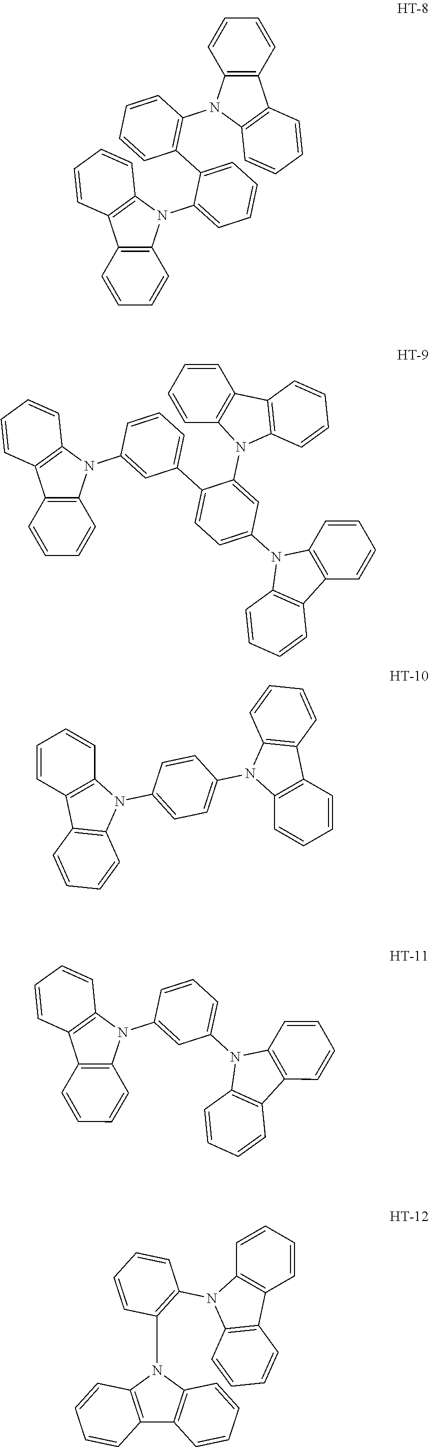

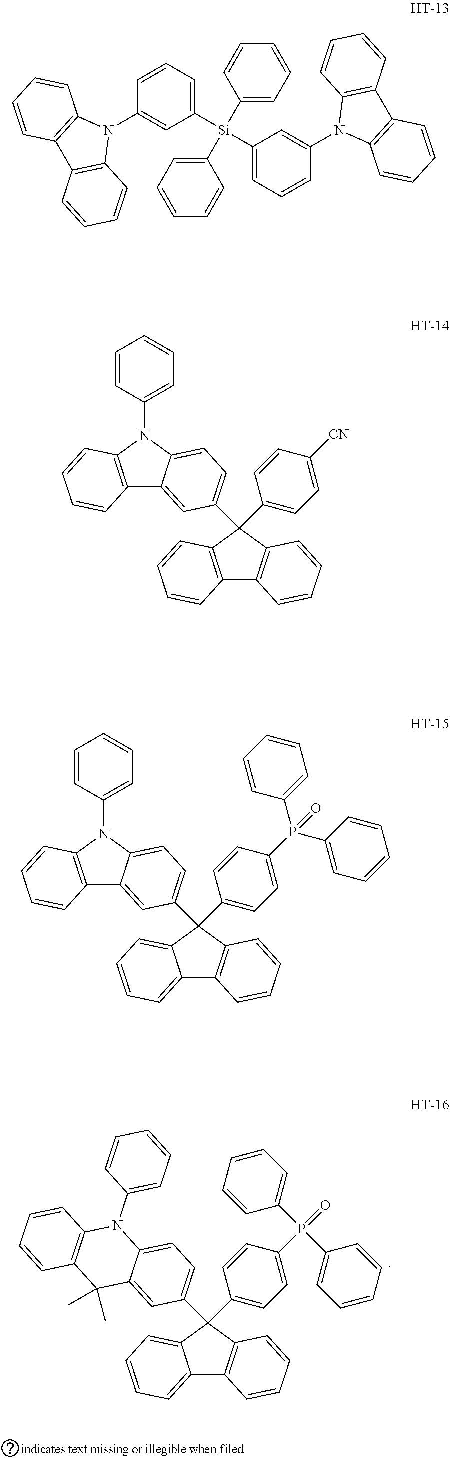 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

The light-emission layer EML may further include a compound represented by Formula HTH-1, but the present disclosure is not limited thereto.

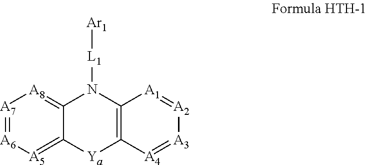

In Formula HTH-1, A₁ through A₈ may each independently by N or CR₁.

For example, A₁ through A₈ may all be CR₁. In one or more embodiments, any one of A₁ through A₉ may be N, and others may be CR₁.

In Formula HTH-1, Yₐ may be a direct linkage, O, S, CR₂R₃, SiR₄R₅, NR₆, or BR₇. For example, it may refer to two 6-membered rings (e.g., two benzene rings) coupled to the nitrogen atom of Formula HTH-1 be connected via a direct linkage, O, S,

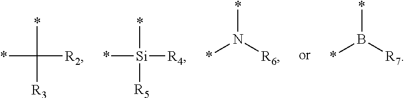

In Formula HTH-1, if (e.g., when) Yₐ is a direct linkage, the compound represented by Formula HTH-1 may include a carbazole moiety.

In Formula HTH-1, L₁ may be a direct linkage, a substituted or unsubstituted arylene group of 6 to 50 ring-forming carbons, or a substituted or unsubstituted heteroarylene group of 2 to 50 ring-forming carbons. For example, in one or more embodiments, L₁ may be a direct linkage, a substituted or unsubstituted phenylene group, a divalent carbazole group, or a divalent biphenyl group, but embodiments of the present disclosure are not limited thereto.

In Formula HTH-1, Ar₁ may be a substituted or unsubstituted aryl group of 6 to 30 ring-forming carbons or a substituted or unsubstituted heteroarylene group of 2 to 30 ring-forming carbons. For example, in one or more embodiments, Ar₁ may be a substituted or unsubstituted phenyl group, a biphenyl group, a carbazole group, a dibenzothiophene group, or a dibenzofuran group, but embodiments of the present disclosure are not limited thereto.

In Formula HTH-1, each of R₁ to R₇ may independently be hydrogen, deuterium, halogens, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbons, a substituted or unsubstituted alkenyl group of 2 to 20 carbons, a substituted or unsubstituted aryl group of 6 to 50 ring-forming carbons, or a substituted or unsubstituted heteroaryl group of 2 to 50 ring-forming carbons. In one or more embodiments, at least one of R₁ to R₇ may bond to an adjacent group to form a ring. For example, in one or more embodiments, each of R₁ to R₇ may independently be hydrogen, deuterium, an unsubstituted methyl group, or an unsubstituted phenyl group.

The light-emission layer EML may include a compound represented by Formula ETH-1 as an electron transport host (ET host), but the present disclosure is not limited thereto.

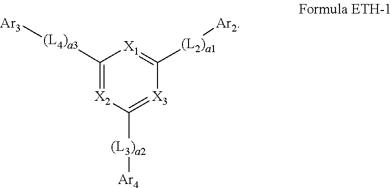

In Formula ETH-1, X₁ may be N or CR₉, X₂ may be N or CR₁₀, X₃ may be N or CR₁₁, and at least one of X₁ through X₃ may be N.

In ETH-1, the R₉ through R₁₁ may each independently be hydrogen, deuterium, a halogen, a hydroxyl group, a cyano group, a nitro group, a substituted or unsubstituted alkyl group having 1 to 20 carbons, a substituted or unsubstituted alkenyl group having 2 to 20 carbons, a substituted or unsubstituted alkoxy group having 1 to 20 carbons, a substituted or unsubstituted alkynyl group having 2 to 20 carbons, a substituted or unsubstituted aryl group having 6 to 50 ring-forming carbons, and a substituted or unsubstituted heteroaryl group having 2 to 50 ring-forming carbons.

In Formula ETH-1, L₂ through L₄ may each independently be a direct linkage, a substituted or unsubstituted arylene group having 6 to 30 ring-forming carbons, or a substituted or unsubstituted heteroarylene group having 2 to 30 ring-forming carbons.

In addition, in the case that the a₁ through a₃ each is an integer greater than or equal to 2, L₂ through L₄ may each independently be a substituted or unsubstituted arylene group having 6 to 30 ring-forming carbons, and a substituted or unsubstituted heteroarylene group having 2 to 30 ring-forming carbons.

In Formula ETH-1, a₁ through a₃ may each independently be an integer greater than or equal to 0 and smaller than or equal to 10.

In Formula ETH-1, the Ar₂ through Ar₄ may each independently be hydrogen, deuterium, a substituted or unsubstituted alkyl group having 1 to 20 carbons, a substituted or unsubstituted aryl group having 6 to 30 ring-forming carbons, and a substituted or unsubstituted heteroaryl group having 2 to 30 ring-forming carbons. For example, Ar₂ through Ar₄ may be a substituted or unsubstituted phenyl group, or a substituted or unsubstituted carbazole group.

A compound represented by the Formula ETH-1 may be represented by ET-1 through ET-12, which are compounds included in Compound Group 2, but the present disclosure is not limited thereto.

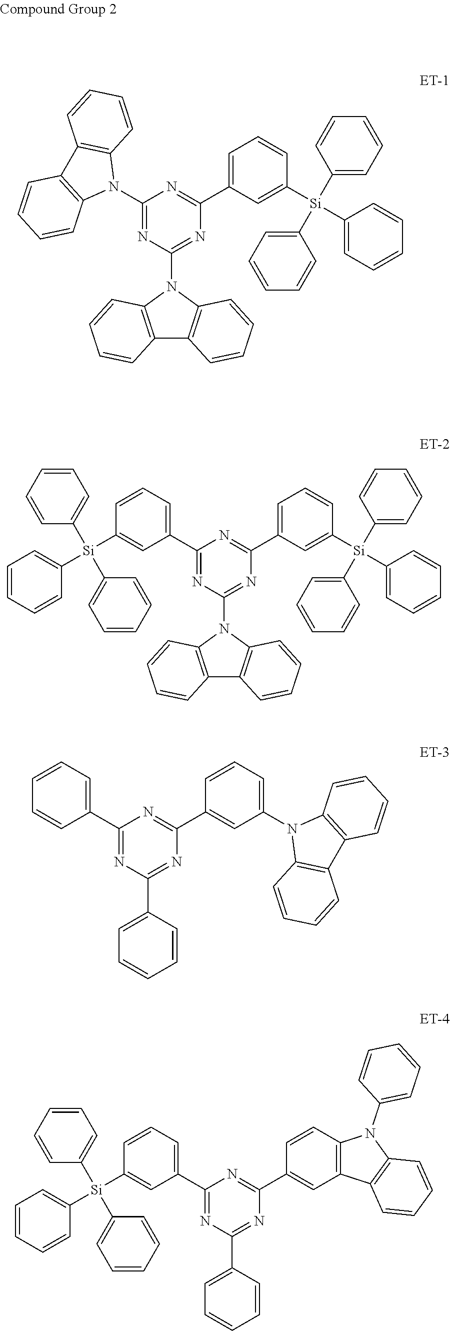 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc(-c2nc(-c3ccccc3)nc(-c3cccc(-n4c5ccccc5c5ccccc54)c3)n2)cc1 ; c1ccc(-c2nc(-c3cccc([Si](c4ccccc4)(c4ccccc4)c4ccccc4)c3)nc(-c3ccc4c(c3)c3ccccc3n4-c3ccccc3)n2)cc1]

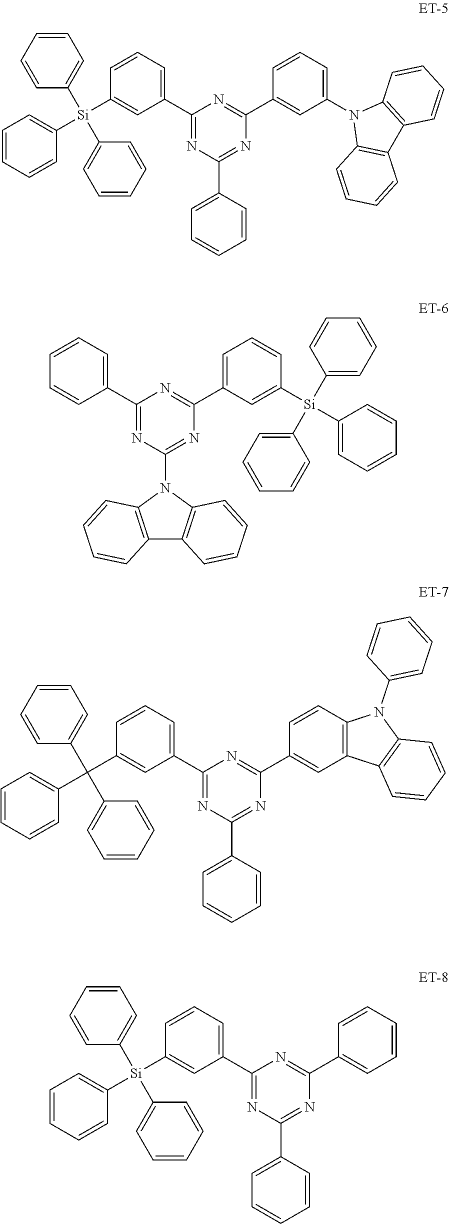 [SMILES: c1ccc(-c2nc(-c3cccc(-n4c5ccccc5c5ccccc54)c3)nc(-c3cccc([Si](c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-n3c4ccccc4c4ccccc43)n2)cc1 ; c1ccc(-c2nc(-c3cccc(C(c4ccccc4)(c4ccccc4)c4ccccc4)c3)nc(-c3ccc4c(c3)c3ccccc3n4-c3ccccc3)n2)cc1 ; c1ccc(-c2nc(-c3ccccc3)nc(-c3cccc([Si](c4ccccc4)(c4ccccc4)c4ccccc4)c3)n2)cc1]

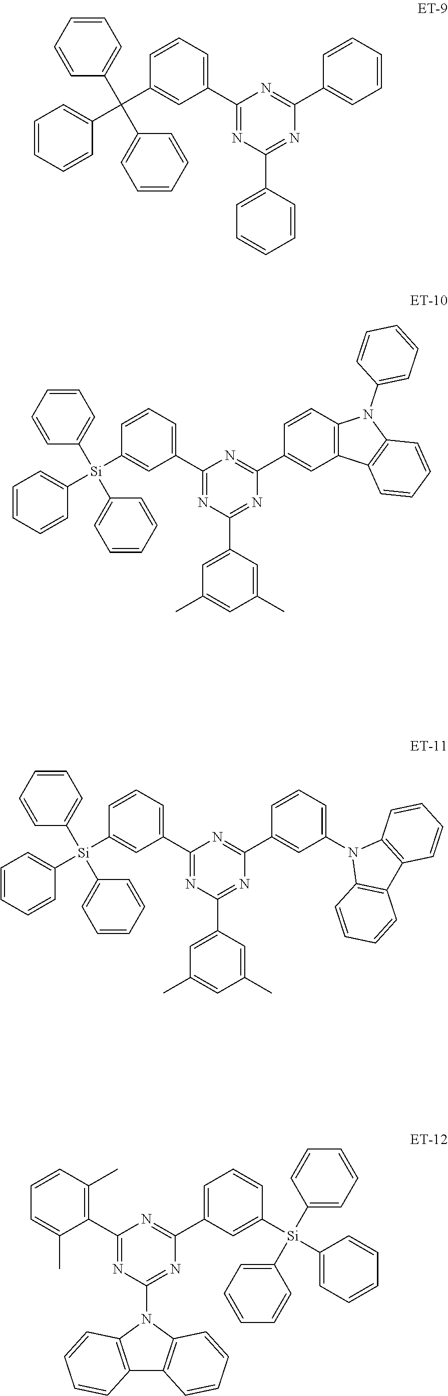 [SMILES: c1ccc(-c2nc(-c3ccccc3)nc(-c3cccc(C(c4ccccc4)(c4ccccc4)c4ccccc4)c3)n2)cc1 ; Cc1cc(C)cc(-c2nc(-c3cccc([Si](c4ccccc4)(c4ccccc4)c4ccccc4)c3)nc(-c3ccc4c(c3)c3ccccc3n4-c3ccccc3)n2)c1 ; Cc1cc(C)cc(-c2nc(-c3cccc(-n4c5ccccc5c5ccccc54)c3)nc(-c3cccc([Si](c4ccccc4)(c4ccccc4)c4ccccc4)c3)n2)c1 ; Cc1cccc(C)c1-c1nc(-c2cccc([Si](c3ccccc3)(c3ccccc3)c3ccccc3)c2)nc(-n2c3ccccc3c3ccccc32)n1]

In a light-emitting diode of one or more embodiments, the light-emission layer EML may include an anthracene derivative, a fluoranthene derivative, a chrysene derivative, a pyrene derivative, a dihydrobenzanthracene derivative, or a triphenylene derivative. For example, in one or more embodiments, the light-emission layer EML may include an anthracene derivative and/or a pyrene derivative, but the present disclosure is not limited thereto.

Other than the above, the light-emission layer EML may use a compound represented by Formula EM-1 as a fluorescence host material, but the present disclosure is not limited thereto.

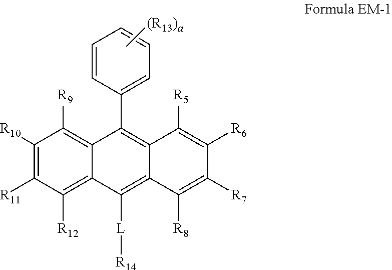

In Formula EM-1, L may be a substituted or unsubstituted arylene group having 6 to 30 ring-forming carbons, or a substituted or unsubstituted heteroarylene group having 2 to 30 ring-forming carbons. Non-limiting examples may be a phenylene group, a biphenylene group, a terphenylene group, a naphthalene group, a phenanthrene group, a pyrene group, a spirofluorenylene group, a fluorenylene group, a dibenzofuranylene group, a dibenzothiophenylene group, or a carbazolylene group.

In Formula EM-1, each of R₅ through R₁₄ may independently be hydrogen, deuterium, halogens, a substituted or unsubstituted oxy group, a substituted or unsubstituted thio group, a substituted or unsubstituted silyl group, a substituted or unsubstituted alkyl group of 1 to 30 carbons, a substituted or unsubstituted alkenyl group of 2 to 30 carbons, a substituted or unsubstituted aryl group of 6 to 30 ring-forming carbons, or a substituted or unsubstituted heteroaryl group of 2 to 30 ring-forming carbons, and/or bonded to an adjacent group to form a ring.

In Formula EM-1, a may be an integer between 0 and 5, inclusive.

The compound represented by Formula EM-1 may be any compound of (e.g., selected from among) Formula E1 through E11, but embodiments of the present disclosure are not limited thereto.

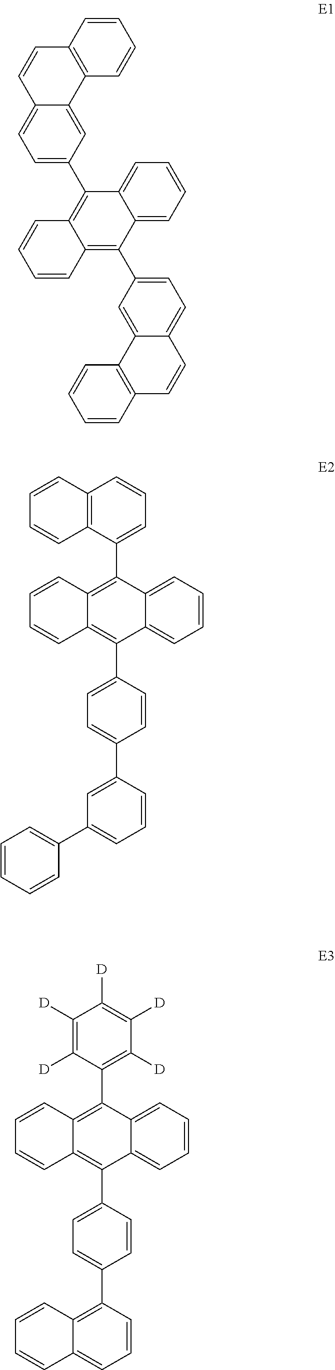

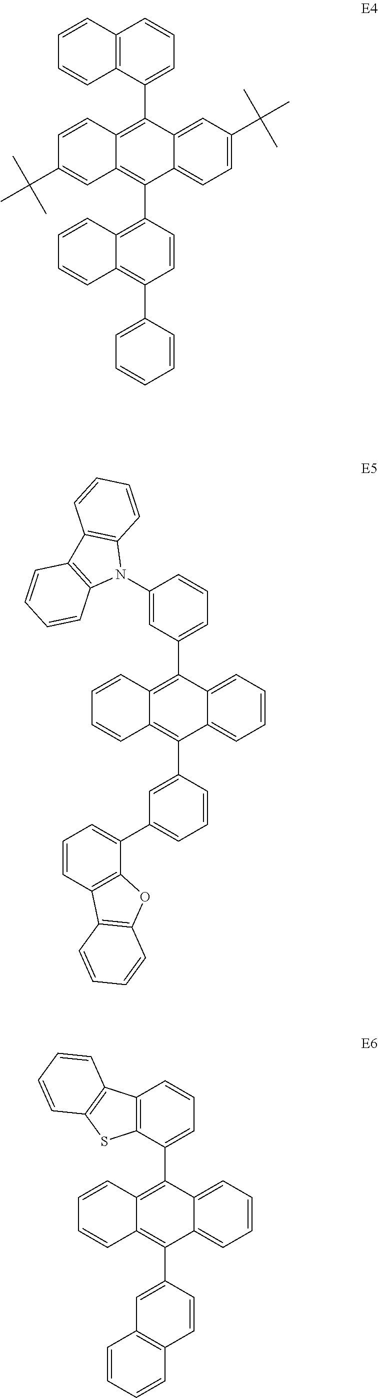

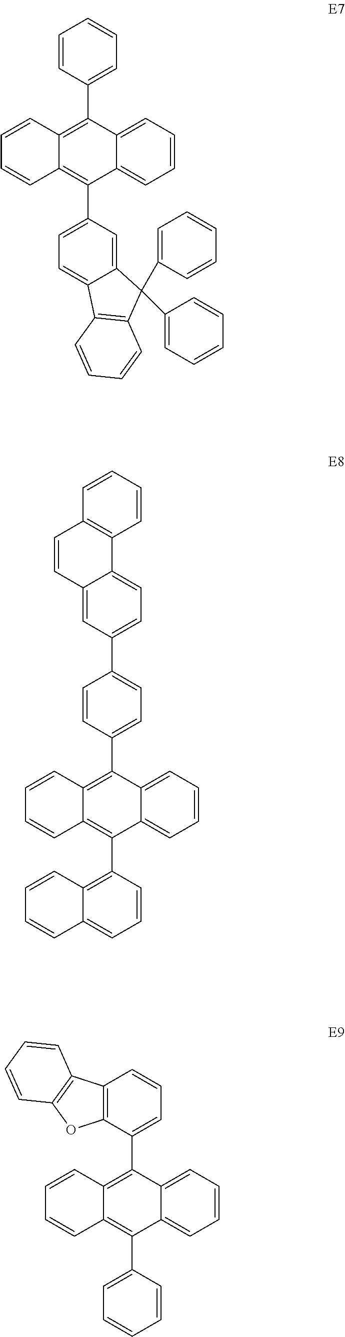

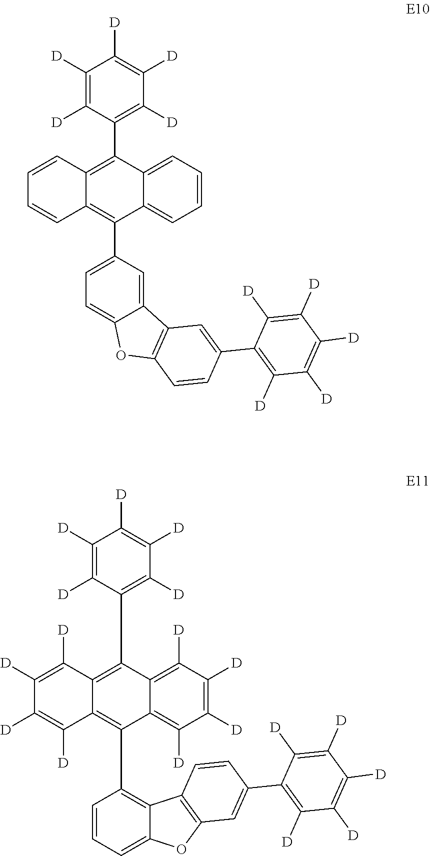 [SMILES: [2H]c1c([2H])c([2H])c(-c2ccc3oc4ccc(-c5c6ccccc6c(-c6c([2H])c([2H])c([2H])c([2H])c6[2H])c6ccccc56)cc4c3c2)c([2H])c1[2H] ; [2H]c1c([2H])c([2H])c(-c2ccc3c(c2)oc2cccc(-c4c5c([2H])c([2H])c([2H])c([2H])c5c(-c5c([2H])c([2H])c([2H])c([2H])c5[2H])c5c([2H])c([2H])c([2H])c([2H])c45)c23)c([2H])c1[2H]]

In one or more embodiments, the light emitting layer EML may further include a compound represented by Formula EM-2 or Formula EM-3. The compound represented by any of Formula EM-2 and Formula EM-3 may be used as a phosphorescence host material, but the present disclosure is not limited thereto.

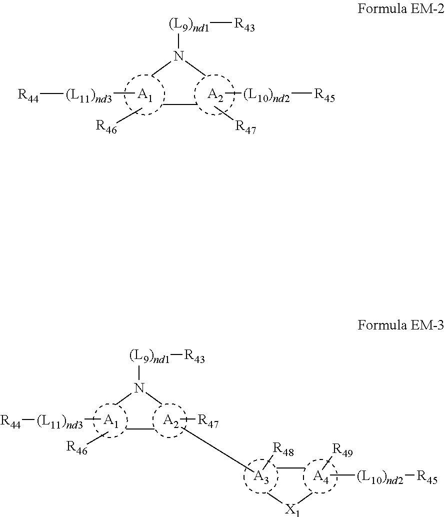

In Formula EM-2 and Formula EM-3, each of rings A₁ through A₄ may independently be a substituted or unsubstituted aryl group of 6 to 30 ring-forming carbons or a substituted or unsubstituted heteroaryl group of 2 to 30 ring-forming carbons. Non-limiting examples thereof may include a benzene group, a naphthalene group, a phenanthrene group, a fluoranthene group, a triphenylene group, a pyrene group, a pyridine group, a pyrimidine group, an indene group, a fluorene group, a spiro-bifluorene group, a benzofluorene group, a dibenzofluorene group, an indole group, a carbazole group, a benzocarbazole group, a dibenzocarbazole group, a furan group, a benzofuran group, a dibenzofuran group, a benzonaphthofuran group, a benzothiophene group, a dibenzothiophene group, a benzonaphthothiophene group, and a dinaphthothiophene group.

In Formula EM-2 and Formula EM-3, nd₁ through nd₃ may independently be 0, 1, or 2, X₁ may be O, S, N-L₁₂-R₅₀, CR₅₁R₅₂, or SiR₅₃R₅₄, and each of L₉ through L₁₂ may independently be a direct linkage, a substituted or unsubstituted arylene group of 6 to 30 ring-forming carbons, or a substituted or unsubstituted heteroarylene group of 2 to 30 ring-forming carbons.

In Formula EM-2 and Formula EM-3, each of R₄₃ to R₄₉ and R₅₀ to R₅₄ may independently be hydrogen, deuterium, halogens, a substituted or unsubstituted amine group, a substituted or unsubstituted thio group, a substituted or unsubstituted oxy group, a substituted or unsubstituted alkyl group of 1 to 20 carbons, a substituted or unsubstituted alkenyl group of 2 to 20 carbons, a substituted or unsubstituted aryl group of 6 to 30 ring-forming carbons, or substituted or unsubstituted heteroaryl group of 2 to 30 ring-forming carbons.

In one or more embodiments, the light-emitting layer EML may further include a material generally suitable in the field as a host material.

For example, in one or more embodiments, the light emitting layer EML may include at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), Bis[2-(diphenylphosphino)phenyl]ether (DPEPO), 4,4′-bis(N-carbazolyl)-1,1′-biphenyl), mCP (1,3-Bis(carbazol-9-yl)benzene (CBP), 2,8-Bis(diphenylphosphoryl)dibenzo[b,d]furan (PPF), 4,4′,4″-Tris(carbazol-9-yl)-triphenylamine (TCTA), or 1,3,5-tris(1-phenyl-1H-benzo[d]imidazol-2-yl)benzene (TPBi) as a host material. However, embodiments of the present disclosure are not limited thereto, for example, a host material, such as tris(8-hydroxyquinolinato)aluminum (Alq₃), 9,10-di(naphthalen-2-yl) anthracene (AND), 2-tert-butyl-9,10-di(naphth-2-yl) anthracene (TBADN), distyrylarylene (DSA), 4,4′-bis(9-carbazolyl)-2,2′-dimethylbiphenyl (CDBP), 2-Methyl-9,10-bis(naphthalen-2-yl) anthracene (MADN), Hexaphenyl cyclotriphosphazene (CP1), 1,4-Bis (triphenylsilyl)benzene (UGH2), Hexaphenylcyclotrisiloxane (DPSiO3), and/or Octaphenylcyclotetrasiloxane (DPSiO4), may be used.

The sensitizer included in the light-emission layer may be configured to transfer energy generated from two types of hosts to a thermally activated delayed fluorescence emitter (TADF emitter), and a lifetime t of triplet energy may be reduced by the sensitizer.

In one or more embodiments of the present disclosure, the phosphorescence sensitizer may include an organo-metallic complex.

A phosphorescence sensitizer of the present disclosure may include a compound represented by Formula P.

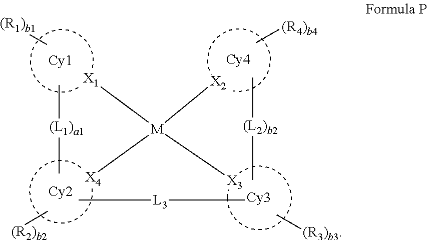

In Formula P, the M may be platinum (Pt), palladium (Pd), copper (Cu), silver (Ag), gold (Au), rhodium (Rh), iridium (Ir), ruthenium (Ru), or Osmium (Os). The X₁ through X₄ may each independently be carbon (C) or nitrogen (N). Ring Cy₁ through ring Cy₄ may each independently be a substituted or unsubstituted carbocyclic ring having 5 to 60 carbons or a substituted or unsubstituted heterocyclic ring having 3 to 60 carbons.

The L₁ through L₃ may each independently be a direct linkage, *—O—*′, *—S—*′, *—C(R₅)(R₆)—*, *—C(R₅)═*′, *═C(R₅)—*′, *—C(R₅)═C(R₆)—*, *—C(═O)—*, *—C(═S)—*, *—C═C—*, *—B(R₅)—*, *—N(R₅)—*′, *—P(R₅)—*, *—Si(R₅)(R₆)—*, *—P(R₅)(R₆)—* or *—Ge(R₅)(R₆)—*′. The a₁ and a₂ may each independently be an integer greater than or equal to 0 and smaller than or equal to 3. In the case that a₁ is 0, Cy₁ and Cy₂ may not be connected to each other through (L₁)a₁. In the case that a₁ is 2 or 3, a plurality of L₁ may be identical to or different from one another. In the case that a₂ is 0, Cy₃ and Cy₄ may not be connected to each other through (L₃)a₂. In the case that a₂ is 2 or 3, a plurality of L₃ may be identical to or different from one another.

The R₁ through R₄ may each independently be hydrogen, deuterium, a halogen, a hydroxyl group, a cyano group, a nitro group, an alkyl group substituted or unsubstituted with at least one R₁₀ₐ and having 1 to 60 carbons, an alkenyl group substituted or unsubstituted with at least one R₁₀ₐ and having 2 to 60 carbons, an alkynyl group substituted or unsubstituted with at least one R₁₀ₐ and having 2 to 60 carbons, an alkoxy group substituted or unsubstituted with at least one R₁₀ₐ and having 1 to 60 carbons, a carbocyclic ring substituted or unsubstituted with at least one R₁₀ₐ and having 3 to 60 carbons, a heterocyclic ring substituted or unsubstituted with at least one R₁₀ₐ and having 3 to 60 carbons, an aryloxy group substituted or unsubstituted with at least one R₁₀ₐ and having 6 to 60 carbons, an arylthio group substituted or unsubstituted with at least one R₁₀ₐ and having 6 to 60 carbons, an arylalkyl group substituted or unsubstituted with at least one R₁₀ₐ and having 7 to 60 carbons, a heteroarylalkyl group substituted or unsubstituted with at least one R₁₀ₐ and having 3 to 60 carbons, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁) or —P(═O)(Q₁)(Q₂).

The b₁ through b₄ may each independently be an integer greater than or equal to 0 and smaller than or equal to 10. The R₁ through R₄ may be optionally a carbocyclic ring having 3 to 20 carbons connected to one another or a heterocyclic ring having 1 to 20 carbons.

The R₁₀ₐ may each independently be a deuterium, a halogen, a hydroxyl group, a cyano group, a nitro group, a carbocyclic ring having 3 to 60 carbons, a heterocyclic ring having 2 to 60 carbons, an aryloxy group having 6 to 60 carbons, an arylthio group having 6 to 60 carbons, an arylalkyl group having 7 to 60 carbons, a heteroarylalkyl group having 3 to 60 carbons, a substituted or unsubstituted alkyl group having 1 to 60 carbons, alkenyl group having 2 to 60 carbons, alkynyl group having 2 to 60 carbons, alkoxy group having 1 to 60 carbons, carbocyclic ring having 3 to 60 carbons, heterocyclic ring having 2 to 60 carbons, aryloxy group having 6 to 60 carbons, arylthio group having 6 to 60 carbons, arylalkyl group having 7 to 60 carbons, or heteroarylalkyl group having 3 to 60 carbons with —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), or —P(═O)(Q₁₁)(Q₁₂).

The Q₁ through Q₃ and Qu through Q₁₃ may each independently be selected from among a substituted or unsubstituted alkyl group having 1 to 60 carbons, alkenyl group having 2 to 60 carbons, alkynyl group having 2 to 60 carbons, alkoxy group having 1 to 60 carbons, carbocyclic ring having 3 to 60 carbons, and heterocyclic ring having 1 to 60 carbons with hydrogen, deuterium, a halogen, a hydroxyl group, a cyano group, a nitro group, an alkyl group having 1 to 60 carbons, an alkoxy group having 1 to 60 carbons, a phenyl group, a biphenyl group, or a combination thereof.

The compound represented by Formula P may be represented by any one of Compound BD-1 through Compound BD-16 included in Compound Group 3, but the present disclosure is not limited thereto.

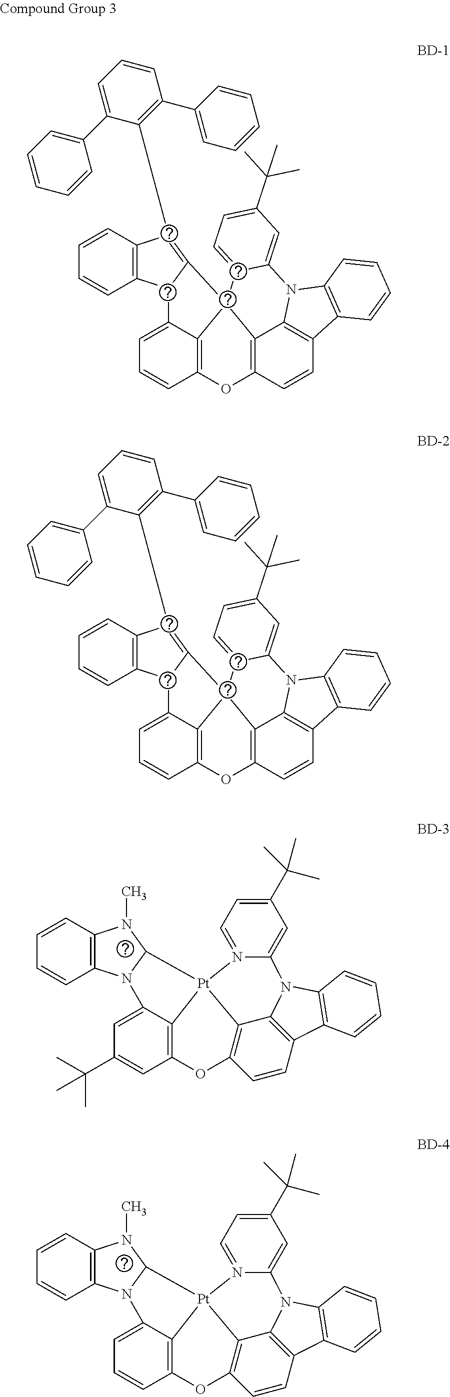

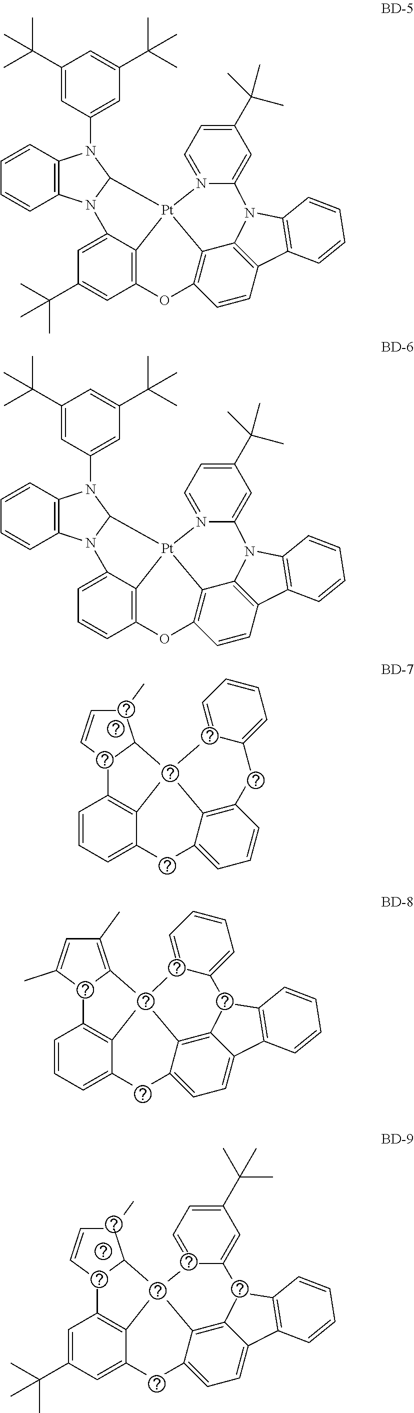

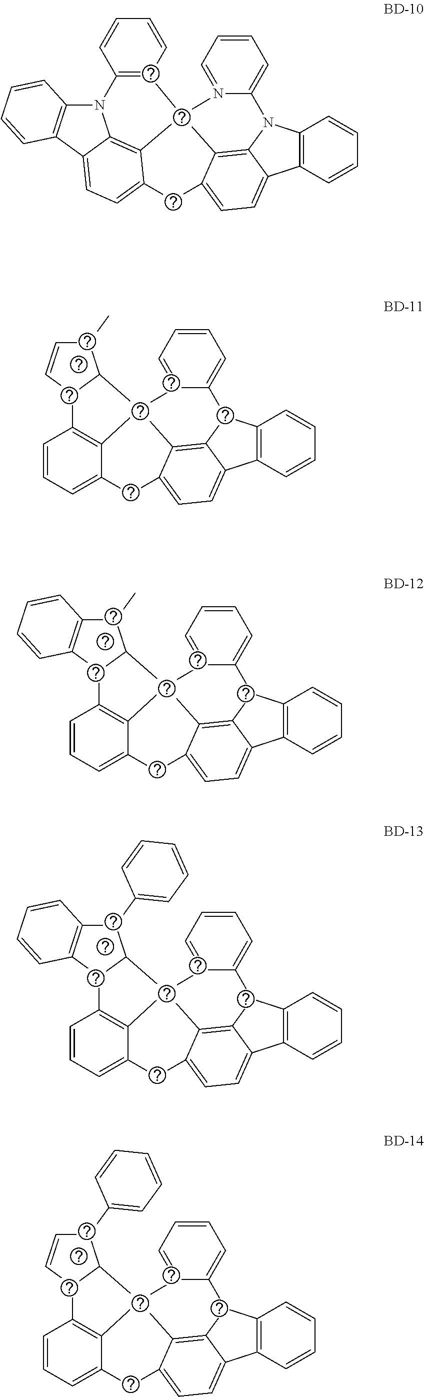

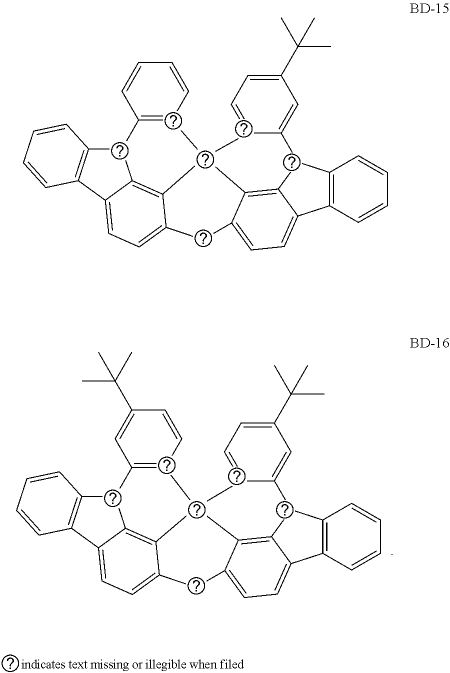

The thermally activated delayed fluorescence emitter (TADF emitter) may receive an exciton through the sensitizer and show eventual light-emission. Here, an up-conversion phenomenon of energy flow from a triplet to a singlet is shown. Due to the up-conversion phenomenon of energy flow, triplet excitons are all converted to light, and current efficiency may be increased.

In one or more embodiments of the present disclosure, a material of the thermally activated delayed fluorescence may include, for example, i) a material including at least one electron donor (e.g., an II electron-rich C3-C60 cyclic group such as a carbazole group) and at least one electron acceptor (e.g., a sulfoxide group, a cyano group, or an II electron-deficient nitrogen-containing C1-C60 cyclic group), and ii) a material including a C8-C60 polycyclic group including two or more condensed cyclic groups sharing a boron (B), but the present disclosure is not limited thereto.

The thermally activated delayed fluorescence emitter (TADF emitter) may include a compound represented by Formula F-a.

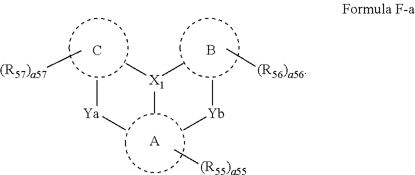

In Formula F-a, the rings A through C may each independently be a substituted or unsubstituted aromatic cyclic hydrocarbon of 6 to 60 ring-forming carbons or a substituted or unsubstituted aromatic heterocyclic ring having 2 to 60 ring-forming carbons.

The Yₐ and Yb may each independently be among O, S, Se, CR₅₈R₅₉, NR₆₀, or SiR₆₁R₆₂.

The X₁ may be B, P or P═O, and R₅₅ through R₆₂ may be the same or different, and each may independently be hydrogen, deuterium, a halogen, a cyano group, a nitro group, an amino group, a substituted or unsubstituted alkyl group of 1 to 30 carbons, a substituted or unsubstituted aryl group of 6 to 60 ring-forming carbons, a substituted or unsubstituted arylamino group, a substituted or unsubstituted cycloalkyl group of 3 to 30 ring-forming carbons, a substituted or unsubstituted heteroaryl group of 2 to 60 ring-forming carbons, a substituted or unsubstituted alkoxy group of 1 to 30 carbons, a substituted or unsubstituted aryloxy group of 6 to 30 carbons, a substituted or unsubstituted arylthiol group of 6 to 30 carbons, a substituted or unsubstituted arylamine group of 5 to 30 carbons, a substituted or unsubstituted alkylsilyl group of 1 to 30 carbons, or a substituted or unsubstituted arylsilyl group of 5 to 30 carbons.

The a₅₅ through a₅₇ may each independently be an integer greater than or equal to 0 and smaller than or equal to 20.

The compound represented by Formula F-a may be represented by any one of Compound D-01 through Compound D-11 included in Compound Group 4, but the present disclosure is not limited thereto.

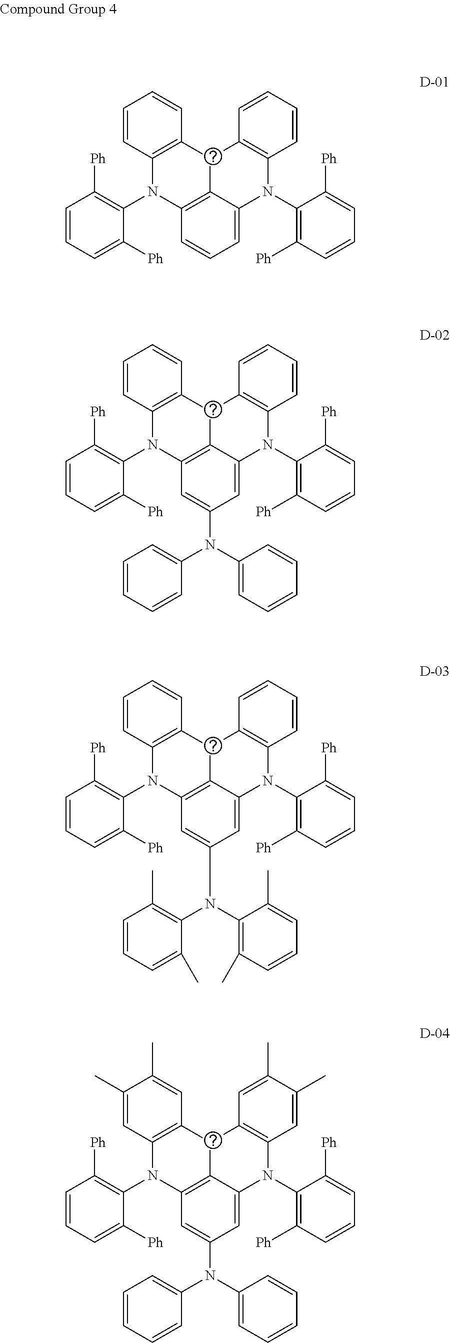 [SMILES: c1ccc(-c2cccc(-c3ccccc3)c2N2c3ccccc3C3c4ccccc4N(c4c(-c5ccccc5)cccc4-c4ccccc4)c4cccc2c43)cc1 ; c1ccc(-c2cccc(-c3ccccc3)c2N2c3ccccc3C3c4ccccc4N(c4c(-c5ccccc5)cccc4-c4ccccc4)c4cc(N(c5ccccc5)c5ccccc5)cc2c43)cc1 ; Cc1cccc(C)c1N(c1cc2c3c(c1)N(c1c(-c4ccccc4)cccc1-c1ccccc1)c1ccccc1C3c1ccccc1N2c1c(-c2ccccc2)cccc1-c1ccccc1)c1c(C)cccc1C ; Cc1cc2c(cc1C)N(c1c(-c3ccccc3)cccc1-c1ccccc1)c1cc(N(c3ccccc3)c3ccccc3)cc3c1C2c1cc(C)c(C)cc1N3c1c(-c2ccccc2)cccc1-c1ccccc1]

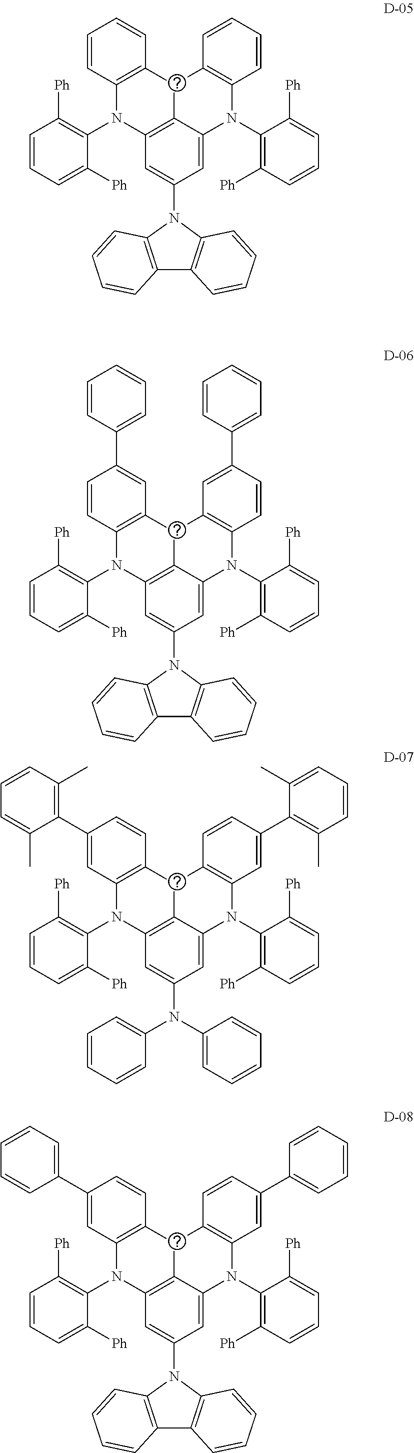

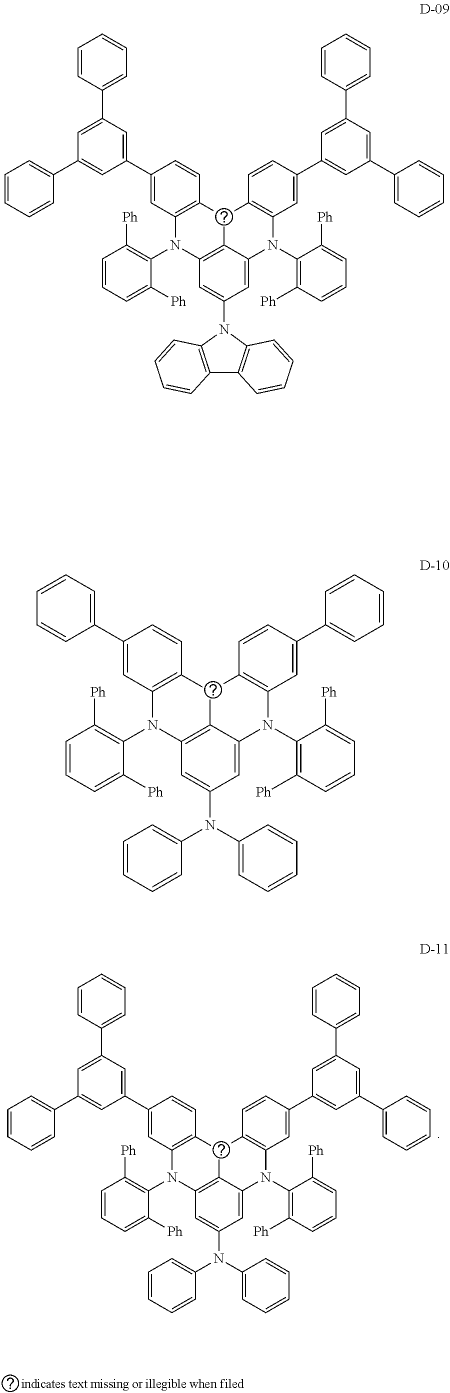 [SMILES: c1ccc(-c2cc(-c3ccccc3)cc(-c3ccc4c(c3)N(c3c(-c5ccccc5)cccc3-c3ccccc3)c3cc(-n5c6ccccc6c6ccccc65)cc5c3C4c3ccc(-c4cc(-c6ccccc6)cc(-c6ccccc6)c4)cc3N5c3c(-c4ccccc4)cccc3-c3ccccc3)c2)cc1 ; c1ccc(-c2ccc3c(c2)N(c2c(-c4ccccc4)cccc2-c2ccccc2)c2cc(N(c4ccccc4)c4ccccc4)cc4c2C3c2ccc(-c3ccccc3)cc2N4c2c(-c3ccccc3)cccc2-c2ccccc2)cc1 ; c1ccc(-c2cc(-c3ccccc3)cc(-c3ccc4c(c3)N(c3c(-c5ccccc5)cccc3-c3ccccc3)c3cc(N(c5ccccc5)c5ccccc5)cc5c3C4c3ccc(-c4cc(-c6ccccc6)cc(-c6ccccc6)c4)cc3N5c3c(-c4ccccc4)cccc3-c3ccccc3)c2)cc1]

Referring to FIG. 2, in one or more embodiments of the present disclosure, stack units in a light-emitting diode may include, for example, a first stack unit 300, a second stack unit 400 vertically laminated on the first stack unit 300, and one or more electric charge generation layers 500 between the first stack unit 300 and the second stack unit 400.

The electric charge generation layer 500 may include a p-type electric charge generation layer pCGL and an n-type electric charge generation layer nCGL, but the present disclosure is not limited thereto. FIG. 2 illustrates that a p-type electric charge generation layer is laminated on an n-type electric charge generation layer, but the present disclosure is not limited to what is illustrated in the figure.

A light-emitting diode according to one or more embodiments of the present disclosure maximizes current efficiency through a lamination structure of the described stack units. Particularly, a decrease in a lifespan of a light-emitting diode of the present disclosure may be minimized by the structure of the first stack unit 300. In addition, current efficiency of a light-emitting diode of the present disclosure may be maximized by a 4-component composition of the second stack unit 400 according to the present disclosure.

In one or more embodiments of the present disclosure, a plurality of light-emission layers included in the first stack unit 300 may include one or more types of a phosphorescence light-emission layer and a fluorescence light-emission layer. One or more light-emission layers EML among the plurality of light-emission layers included in the second stack unit 400 may be a TADF light-emission layer configured to emit thermally activated delayed fluorescence. Only the second stack of a light-emitting diode according to one or more embodiments of the present disclosure may include a TADF light-emission layer 430, and the first stack unit 300 uses a light-emission layer including one or more types of a phosphorescence light-emission layer and a fluorescence light-emission layer to increase process efficiency, optimize a lifespan of a light-emitting diode, and increase current efficiency.

In one or more embodiments of the present disclosure, a light-emitting diode 1000 including a second stack unit 400 thicker than the first stack unit 300 may have current efficiency increased by a large extent in comparison to a conventional light-emitting diode 1.

In one or more embodiments of the present disclosure, a thickness of the second stack unit 400 may be thicker than a thickness of the first stack unit 300 by 50 angstroms (Å) to 300 Å. In the thickness range of the second stack unit 400, a lifespan of a light-emitting diode 1000 may be optimized, and current efficiency may be maximized. A thickness of the second stack unit 400 may be thicker than a thickness of the first stack unit 300 by 100 Å to 300 Å, or by 150 Å to 250 Å, but the present disclosure is not limited thereto.

In one or more embodiments of the present disclosure, λₘₐₓ of each phosphorescence sensitizer of red (R) and/or green (G) included in the second stack unit may satisfy the following Inequality 1 in relation with λₘₐₓ of a phosphorescence dopant included in the first stack unit.

$${λ}_{max} of phosphorescence dopant of the first stack unit - {λ}_{max} of phosphorescence sensitizer of the second stack unit > 1 nm . \qquad Inequality 1$$

That is, a maximum wavelength λₘₐₓ of a red sensitizer and a green sensitizer included in the second stack unit may be a short wavelength in comparison to a maximum wavelength of a phosphorescence dopant applied to a light-emission layer of the first stack unit. In one or more embodiments, Foster Resonance Energy Transfer (FRET) from a sensitizer to a TADF emitter is efficient, and a triplet exciton for light-emission may be obtained. Intermolecular spacing between the sensitizer and the TADF emitter may be maintained to suppress transfer of Dexter energy, which may lead to triplet non-light-emission loss. Accordingly, a triplet may not be quenched. Therefore, a light-emitting diode of the present disclosure may maximize efficiency through control of a maximum wavelength of a phosphorescence sensitizer of the second stack unit and FRET improvement.

In one or more embodiments of the present disclosure, a triplet energy (T1 (TADF)) of a thermally activated delayed fluorescence emitter included in the second stack unit and a triplet energy (T1 (sensitizer)) of each sensitizer of red (R), green (G) and blue 9B) of the second stack may satisfy at least one of the following Inequality 2-1 through Inequality 2-3.

A triplet energy (T1 (TADF)) of the thermally activated delayed fluorescence emitter included in the second stack unit and a triplet energy (T1 (sensitizer)) of each sensitizer of red (R), green (G) and blue (B) of the second stack may satisfy all the following Inequality 2-1 through Inequality 2-3, but the present disclosure is not limited thereto.

$$Δ {T}_{R} = T 1 ( Red sensitizer ) - T 1 ( Red TADF ) > 0.02 eV . \qquad Inequality 2 ‐ 1$$

$$Δ {T}_{G} = T 1 ( Green sensitizer ) - T 1 ( Green TADF ) > 0.02 eV . \qquad Inequality 2 ‐ 2$$

$$Δ {T}_{B} = T 1 ( Blue sensitizer ) - T 1 ( Blue TADF ) > 0.02 eV . \qquad Inequality 2 ‐ 3$$

As a difference between a triplet energy level (eV) of the thermally activated delayed fluorescence emitter included in the second stack unit and a triplet energy level (eV) of the sensitizer included in each light-emission layer of the second stack satisfies the above range, up-conversion from a triplet state to a singlet state in the thermally activated delayed fluorescence emitter may be effectively performed, and current efficiency of a light-emitting diode may be improved. The energy difference may be evaluated, for example, through photo-luminescence spectrum analysis, or density functional theory (DFT) method of a Gaussian program, but the present disclosure is not limited thereto.

A plurality of light-emission layers included in the first stack unit 300 may include one or more types of a phosphorescence light-emission layer and a fluorescence light-emission layer.

In one or more embodiments of the present disclosure, the phosphorescence light-emission layer and the fluorescence light-emission layer may include a plurality of light-emission units, and a phosphorescence or fluorescence dopant.

In one or more embodiments of the present disclosure, a light-emission layer of the first stack unit 300 may include a compound represented by Formula M-a and Formula M-b. A compound represented by Formula M-a and Formula M-b may be used as a phosphorescence dopant material, but the present disclosure is not limited thereto.

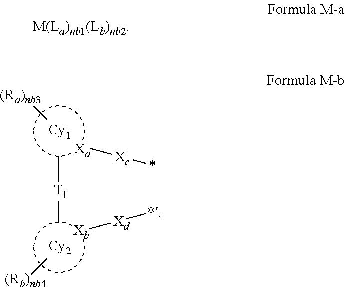

In Formula M-a and Formula M-b, M may be a transition metal (e.g., Iridium (Ir), Platinum (Pt), Gold (Au), Titanium (Ti), Hafnium (Hf), Tantalum (Ta), Tungsten (W), Rhenium (Re), or Osmium (Os), and La may be a ligand represented by Formula M-b.

In Formula M-a, nb1 may be 1, 2, or 3, and if (e.g., when) nb1 is 2 or greater, 2 or more La(s) may be the same or different, and Lb may be an organic ligand such as halogens (e.g. Cl and/or F), a diketone ligand (e.g. acetylacetonate, 1,3-diphenyl-1,3-propanedionate, 2,2,6,6-tetramethyl-3,5-heptanedionate, and/or hexafluoroacetonate), or a carboxylic acid ligand (e.g. picolinate, dimethyl-3-pyrazolcarboxylate, and/or benzoate), and/or the like, but embodiments of the present disclosure are not limited thereto.

In Formula M-a, nb2 may be 0, 1, 2, 3, or 4, if (e.g., when) nb2 is 2 or greater, 2 or more Lb(s) may be the same or different, T₁ may be a direct linkage, *—O—*, *—S—*, *—N(Q₁)*—C(═O)—*, *C(Q₁)═C(Q₂)—*, *—C(Q₁)=*, *—C(Q₁)(Q₂)—*, or *═C(Q₁)—*, each of Xₐ and X_{b} may independently be C or N, each of X_{c} and X_{d} may independently be a chemical linkage (e.g. a coordination bond or a covalent bond), O, S, N(Q₃), B(Q₃), P(Q₃), C(Q₃)(Q₄), or Si(Q₃)(Q₄), and each of ring Cy₁ and ring Cy₂ may independently be a substituted or unsubstituted carbocyclic ring of 3 to 60 ring-forming carbons or a substituted or unsubstituted heterocyclic ring of 1 to 60 ring-forming carbons.

In Formula M-b, each of Rₐ and R_{b} may independently be hydrogen, deuterium, halogens, a hydroxyl group, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbons, a substituted or substituted alkenyl group of 2 to 20 carbons, a substituted or unsubstituted aryl group of 6 to 60 ring-forming carbons, or a substituted or unsubstituted heteroaryl group of 2 to 60 ring-forming carbons.

In Formula M-a, each of Q₁ to Q₄ may independently be hydrogen, deuterium, halogens, a hydroxyl group, a cyano group, a nitro group, a substituted or unsubstituted alkyl group of 1 to 30 carbons, a substituted or unsubstituted alkenyl group of 1 to 30 carbons, a substituted or unsubstituted alkynyl group of 2 to 30 carbons, a substituted or unsubstituted alkoxy group of 1 to 30 carbons, a substituted or unsubstituted aryl group of 6 to 60 ring-forming carbons, or a substituted or unsubstituted heteroaryl group of 2 to 60 ring-forming carbons.

In Formula M-b, each of nb3 and nb4 may independently be an integer between 0 and 10, inclusive.

In Formula M-b, if (e.g., when) nb1 is 2 or greater, 2 rings Cy₁ among 2 or more La(s) may be optionally linked to each other via T₂, which is a linking group, and/or two rings Cy₂ may be optionally linked to each other via T₃, which is a linking group.

In Formula M-b, each of * and *′ may be a binding site to M of Formula M-a.

In addition, a light-emission layer EML may include a compound represented by Formula F-a as a fluorescence dopant.

In one or more embodiments, the light-emitting layer EML may further include at least one of perylene and derivatives thereof (e.g., 2,5,8,11-Tetra-t-butylperylene (TBP)), pyrene and derivatives thereof (e.g., 1,1-dipyrene, 1,4-dipyrenylbenzene, and 1,4-Bis(N, N-Diphenylamino)pyrene), and/or styryl derivatives (e.g., 1,4-bis[2-(3-N-ethylcarbazolyl) vinyl]benzene (BCzVB), 4-(di-p-tolylamino)-4′-[(di-p-tolylamino) styryl]stilbene (DPAVB), and N-(4-((E)-2-(6-((E)-4-(diphenylamino) styryl) naphthalen-2-yl) vinyl)phenyl)-N-phenylbenzenamine (NBDAVBi)), and 4′-bis[2-(4-(N,N-diphenylamino)phenyl) vinyl]biphenyl (DPAVBi), or the like, as a dopant material, but the present disclosure is not limited thereto.

In one or more embodiments, the light-emitting layer EML may further include a suitable phosphorescence dopant material. For example, a metal complex including iridium (Ir), platinum (Pt), osmium (Os), gold (Au), titanium (Ti), zirconium (Zr), hafnium (Hf), europium (Eu), terbium (Tb), or thulium (Tm) may be used. For example, iridium (III) bis(4,6-difluorophenylpyridinato-N,C2′) picolinate (FIrpic), Bis(2,4-difluorophenylpyridinato)-tetrakis(1-pyrazolyl) borate iridium (III)(Fir6), or platinum octaethyl porphyrin (PtOEP) may be used as a phosphorescence dopant. Nonetheless, embodiments of the present disclosure are not limited thereto.

In one or more embodiments, the light-emitting layer EML may be a quantum dot.

In one or more embodiments, a quantum dot may refer to a crystal of a semiconductor compound and may have selected color of emitted light based on the size of the crystal. Accordingly, the quantum dot may have one or more suitable colors of emitted light, such as blue, red, or green.

In one or more embodiments, a diameter of the quantum dot may be, for example, in a range of 1 nanometer (nm) to 10 nm.

In addition, the quantum dot may be spherical nanoparticles, pyramidal nanoparticles, multi-arm nanoparticles, cubic nanoparticles, nanotubes, nanowires, nanofibers, nanoplates, and/or the like.

The quantum dot may be a Group III-VI compound, a Group II-VI compound, a Group III-V compound, a Group I-III-VI compound, a Group IV-VI compound, a Group IV element, a Group IV compound, or any (e.g., any suitable) combination thereof.

In one or more embodiments of the present disclosure, the phosphorescence or fluorescence dopant may be included in an amount of 0.01 to 30 parts by weight with respect to 100 parts by weight of the light-emission layer composition. In the range of the phosphorescence or fluorescence dopant, a lifespan of a light-emitting diode of the present disclosure may be optimized. The phosphorescence or fluorescence dopant may be included in an amount of 0.5 to 25 parts by weight, or 1 to 20 parts by weight with respect to 100 parts by weight of the light-emission layer composition, but the present disclosure is not limited thereto.

In one or more embodiments of the present disclosure, the stack unit may include a hole functional layer, a plurality of light-emission layer and an electron functional layer, the hole functional layer may include a hole transport layer, a hole injection layer, a light-emission auxiliary layer, or a combination thereof, and the electron functional layer may include an electron transport layer, an electron injection layer, a barrier film layer, a buffer layer, or a combination thereof.

The hole functional layer may be provided on a first electrode, and arranged between the first electrode and the light-emission layer. The hole functional layer may be configured to facilitate transport of a hole from the first electrode to the light-emission layer and include a hole transport layer, a hole injection layer, a light-emission auxiliary layer, or a combination thereof. The hole functional layer HFL may have a single layer structure including (e.g., consisting of) a single layer including (e.g., consisting of) a single material, a single layer structure including (e.g., consisting of) a single layer including a plurality of different materials, or a multi-layer structure including (e.g., consisting of) a plurality of layers including a plurality of different materials.

A material of the hole functional layer will be described in detail in description of a display device.

The electron functional layer EFL may be arranged between a second electrode and the light-emission layer. The electron functional layer may be configured to facilitate transfer of an electron from the second electrode to the light-emission layer. The electron functional layer may include an electron transport layer, an electron injection layer, barrier film layer, a buffer layer, or a combination thereof. Similar to the hole functional layer, the electron functional layer may have a single layer structure including (e.g., consisting of) a single layer including (e.g., consisting of) a single material, a single layer structure including (e.g., consisting of) a single layer including a plurality of different materials, or a multi-layer structure including (e.g., consisting of) a plurality of layers including a plurality of different materials. A material of the electron functional layer will be described in detail in description of a display device.

In one or more embodiments of the present disclosure, the light-emission auxiliary layer BIL may be included in a blue light-emission layer. The light-emission auxiliary layer BIL included in the blue light-emission layer may be configured to control hole-charge balance to improve light-generation efficiency of a light-emitting diode.

The emission auxiliary layer is a layer configured to compensate for an optical resonance distance according to a wavelength of light emitted from the light-emitting layer to increase light-emitting efficiency, and the electron blocking layer EBL is a layer configured to prevent or reduce leakage of an electron from the light-emitting layer to the hole functional layer HFL. The materials that may be included in the hole functional layer HFL may be included in the light-emission auxiliary layer and the light blocking layer EBL. The light-emission layer EML may be provided on the hole functional layer HFL. The light-emission layer EML may have a single layer structure including (e.g., consisting of) a single layer including (e.g., consisting of) a single material, a single layer structure including (e.g., consisting of) a single layer including a plurality of different materials, or a multi-layer structure including (e.g., consisting of) a plurality of layers including a plurality of different materials

A display device according to the present disclosure may be a thin film transistor including a source electrode, a drain electrode, and an activation layer, and a light-emitting diode electrically connected to one or more types of the source electrode and the drain electrode. The light-emitting diode may include a first electrode, a second electrode arranged on the first electrode, and stack units arranged between the first electrode and the second electrode, vertically laminated to form a plurality of layers, and including a plurality of light-emission layers EML on each layer. One or more light-emission layers among the plurality of light-emission layers EML included in at least an uppermost stack unit among the laminated stack units may be a thermally activated delayed fluorescence light-emission layer configured to emit thermally activated delayed fluorescence, and at least one stack unit below the uppermost stack unit may include at least one of a phosphorescence light-emission layer or a fluorescence light-emission layer.

Hereinafter, certain embodiments of the present disclosure will be described with reference to the accompanying drawings to describe a display device and an electronic device including the display device.

FIG. 4 is a plan view illustrating a display device according to one or more embodiments of the present disclosure. The display device 200′ may be defined with a display area DA and a surrounding area NA defined outside of the display area. The display area DA may be an area configured to display an image and the surrounding area NA may be an area not configured to display an image. In certain embodiments, the surrounding area NA may not be provided.

Pixel areas PA1, PA2, and PA3 and a non-pixel area NPA may be defined in the display area DA. As light-emitting diodes ED1, ED2, and ED3 may be arranged to correspond to the pixel areas PA1, PA2, and PA3, respectively, the pixel areas may be areas configured to display emitted light. The non-pixel area NPA may be an area defined among the pixel areas PA1, PA2, and PA3 and correspond to the pixel defining film.

Although it is illustrated in FIG. 4 that the pixel areas PA1, PA2, and PA3 have the same area, embodiments of the present disclosure are not limited to what are illustrated in FIG. 4, for example, in one or more embodiments, some of the pixel areas PA1, PA2, and PA3 may have different areas.

Referring to FIG. 4, first to third directions DR1, DR2 and DR3 may be defined, in which a first direction DR1 and a second direction DR2 may intersect with each other in directions flush with a display device 200′ illustrated in FIG. 4. A third direction DR3 may be in a direction of thickness of the display device, for example normal to a plane defined by the first direction DR1 and the second direction DR2.

In one or more embodiments of the present disclosure, the display device may include a substrate BS, a circuit layer CL and a display device layer EDL. The circuit layer CL and the display device layer EDL may be arranged on the substrate BS. The substrate BS may include, glass, ceramic, a metal, or a polymer resin such as a polyimide. Yet, embodiments of the present disclosure are not limited thereto, and the substrate BS may be an inorganic layer, an organic layer, or a composite material layer, and may be constituted with a single layer and a multilayer.

The circuit layer CL may be arranged on the substrate BS and include a plurality of wires and a plurality of transistors. In one or more embodiments, the circuit layer CL may include pixel transistors configured to drive light-emitting diodes ED1, ED2, and ED3 of the display device layer EDL. The circuit layer CL may include surrounding transistors arranged on a surrounding area NA and configured to output signals to control pixel transistors.

The display device layer EDL may include a pixel defining film PDL, light-emitting diodes ED1, ED2, and ED3, and an encapsulation layer TFE.

The pixel defining film PDL may include at least one insulating material such as a polyimide, a polyamide, an acryl resin, a benzocyclobutene-based resin, or a phenol resin.

In one or more embodiments, at least some of the light-emitting diodes ED1, ED2, and ED3 may be configured to emit light in a different wavelength range. For example, in one or more embodiments, a first light-emitting diode ED1 may be configured to emit red light, a second light-emitting diode ED2 may be configured to emit green light, and a third light-emitting diode ED3 may be configured to emit blue light. However, embodiments of the present disclosure are not limited to this configuration, for example, a first through a third light-emitting diodes may be configured to emit light in substantially the same wavelength range, such as blue light. Nonetheless, the present disclosure is not limited thereto.

The encapsulation layer TFE may be configured to seal off the light-emitting diodes ED1, ED2, and ED3 to protect the light-emitting diodes ED1, ED2, and ED3 from moisture, oxygen, and/or foreign substances. In one or more embodiments, the encapsulation layer TFE may be constituted with a single layer. In one or more embodiments, the encapsulation layer TFE may be constituted with multiple layers including an encapsulation organic film and an encapsulation inorganic film.

The encapsulation organic film may include at least one of acrylic compounds, epoxy compounds, or the like. In one or more embodiments, the encapsulation organic film may contain, but may not be limited to, one or more of photo-polymerizable organic materials. The encapsulation inorganic film may include, but may not be limited to, silicon nitride, silicon oxynitride, silicon oxide, titanium oxide, and/or aluminum oxide.

An optical layer arranged on the display device layer EDL may be further included, but a display device according to one or more embodiments of the present disclosure is not limited thereto. The optical layer may be configured to reduce reflected light of external light. The optical layer may include a color conversion layer, a touch-sensor layer, or a polarizing layer, but the present disclosure is not limited thereto.

The display device according to one or more embodiments of the present disclosure may further include a touch-sensor layer arranged on the display device layer EDL, but an embodiment of the present disclosure is not limited thereto. The touch-sensor layer may detect a coordination of a touch where a touch occurs. The touch-sensor layer may be interposed between the display device layer EDL and the optical layer.

A display device according to one or more embodiments of the present disclosure may include a hole functional layer HFL and an electron functional layer EFL, but the present disclosure is not limited thereto.

The positions of the hole functional layer HFL and the electron functional layer EFL may be exchanged based on whether each of the first electrode EL1 and the second electrode EL2 is positively charged or negatively charged.

The hole functional layer HFL may be manufactured using one or more suitable methods, such as a vacuum deposition method, a spin coating method, a Langmuir-Blodgett (LB) method, an inkjet printing method, a casting method, a laser printing method, and/or a laser induced thermal imaging (LITI) method.

In one or more embodiments, the hole functional layer HFL may include a compound represented by Formula H-1, a compound represented by Formula H-2, and/or a (e.g., any suitable) combination thereof included in the electron transport host.

In one or more embodiments, the hole functional layer HFL may include at least of 4,4′,4″-tris-N-(2-naphthyl)-N-phenyl-amino}-triphenylamine (2-TNATA), poly(3,4-ethylenedioxythiophene)/poly(4-styrenesulfonate)(PEDOT/PSS), 4,4′,4″-tris(3-methylphenylphenylamino)triphenylamine (m-MTDATA), 4,4′4″-Tris(N,N-diphenylamino)triphenylamine (TDATA), a phthalocyanine compound, such as copper phthalocyanine, N,N′-diphenyl-N,N′-bis-[4-(phenyl-m-tolyl-amino)-phenyl]-biphenyl-4,4′-diamine (DNTPD), polyaniline/dodecylbenzenesulfonic acid (PANI/DBSA), N,N′-di(naphthalen-1-yl)-N,N′-diphenyl-benzidine (NPB), triphenylamine-containing polyetherketone (TPAPEK), 4-isopropyl-4′-methyldiphenyliodonium[tetrakis(pentafluorophenyl) borate], or dipyrazino[2,3-f: 2′,3′-h]quinoxaline-2,3,6,7,10,11-hexacarbonitrile (HAT-CN), but the present disclosure is not limited thereto.

In one or more embodiments, the hole functional layer HFL may include a carbazole-based derivative, such as polyvinyl carbazole and/or N-phenyl carbazole, a fluorene-based derivative, a triphenylamine-based derivative, such as 4,4′4″-Tris-(carbazol-9-yl)-triphenylamine (TCTA), N,N′-bis(3-methylphenyl)-N,N′-diphenyl-[1,1′-biphenyl]-4,4′-diamine (TPD), N,N′-di(naphthalen-1-yl)-N,N′-diphenyl-benzidine (NPB), 4,4′-Cyclohexylidene bis[N,N-bis(4-methylphenyl)benzenamine] (TAPC), 4,4′-Bis[N,N′-(3-tolyl)amino]-3,3′-dimethylbiphenyl (HMTPD), and/or 1,3-Bis(N-carbazolyl)benzene (mCP), but the present disclosure is not limited thereto.

In one or more embodiments, the hole functional layer HFL may include 1,3-bis(1,8-dimethyl-9H-carbazol-9-yl)benzene (mDCP), 9-(4-tert-Butylphenyl)-3,6-bis(triphenylsilyl)-9H-carbazole (CzSi), or 9-phenyl-9H-3,9′-bicarbazole (CCP), but the present disclosure is not limited thereto.

The hole functional layer HFL may have a thickness of about 50 ångströms (Å) to about 10000 Å, e.g. about 100 Å to about 5000 Å. If (e.g., when) the hole functional layer HFL includes a hole injection layer HIL, a hole transport layer HTL, or a combination thereof, the hole injection layer HIL may have a thickness of about 100 Å to about 9000 Å, e.g., about 100 Å to about 1000 Å, and the hole transport layer may have a thickness of about 50 Å to about 2000 Å, e.g., about 100 Å to about 1500 Å. When the thicknesses of the hole functional layer HFL, the hole injection layer HIL, and the hole transport layer HTL satisfy their respective above-described ranges, satisfactory level of hole transport properties may be obtained without a substantial increase in driving voltage.

In one or more embodiments, the hole functional layer HFL may further include, in addition to one or more of the above-described materials, a charge-generation material to increase conductivity. The charge-generation material may be uniformly (e.g., substantially uniformly) or non-uniformly dispersed in the hole functional layer HFL.

The charge-generation material may be, for example, a p-dopant, but the present disclosure is not limited thereto.

According to one or more embodiments of the present disclosure, the p-dopant may include at least one of a halogenated metal compound (e.g., a metal halide), a quinone derivative, a metal oxide, or a cyano group-containing compound, but embodiments of the present disclosure are not limited thereto. For example, the p-dopant may include a halogenated metal compound, such as Cul and/or RbI, a quinone derivative, such as tetracyanoquinodimethane (TCNQ) and/or 2,3,5,6-tetrafluoro-7,7,8,8-tetracyanoquinodimethane (F4-TCNQ), a cyano-group containing compound, such as dipyrazino[2,3-f: 2′3′-h]quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or a metal oxide, such as a tungsten oxide and/or a molybdenum oxide, but embodiments of the present disclosure are not limited thereto.

As described above, the hole functional layer HFL may further include at least one of a buffer layer and an electron blocking layer EBL in addition to a hole injection layer HIL and a hole transport layer HTL. The buffer layer may be configured to compensate for a resonance distance according to a wavelength of emitted light to increase light-emission efficiency. A material included in the buffer layer may be used as a material to be included in the hole functional layer HFL.

The electron blocking layer EBL is a layer that is configured to prevent or reduce the injection of electrons from the electron functional layer EFL to the hole functional layer HFL.

An electron functional layer EFL may include at least one of a hole blocking layer HBL, an electron transport layer ETL and an electron injection layer EIL, but the present disclosure is not limited thereto.

The electron functional layer EFL may have a single layer including (e.g., consisting of) a single material, a single layer including (e.g., consisting of) a plurality of different materials, or a multilayer structure having a plurality of layers including (e.g., consisting of) a plurality of different materials. For example, in one or more embodiments, the electron functional layer EFL may have a single layer structure of an electron injection layer EIL or an electron transport layer ETL, or a single layer structure including (e.g., consisting of) an electron injection material and/or an electron transport material. In one or more embodiments, the electron functional layer EFL may have a single layer structure including (e.g., consisting of) a plurality of different materials, or a structure, in which constituting layers are sequentially stacked from the light-emitting layer EML, of an electron transport layer ETL/electron injection layer EIL or a hole blocking layer HBL/electron transport layer ETL/electron injection layer EIL, but embodiments of the present disclosure are not limited thereto.

A thickness of the electron functional layer EFL may be, for example, from about 1000 Å to 1500 Å.

The electron functional layer EFL may be manufactured by utilizing a method selected from among vacuum deposition, spin coating, Langmuir-Blodgett (LB) casting, ink-jet printing, laser induced thermal imaging (LITI), and the like.

In one or more embodiments, the electron functional layer EFL may include a compound represented by Formula ET-1 and included in the electron transport host.

In one or more embodiments, the electron functional layer EFL may include an anthracene-based compound. However, embodiments of the present disclosure are not limited thereto, and the electron functional layer EFL may include, for example, 2,9-Dimethyl-4,7-diphenyl-1,10-phenanthroline (BCP), Tris(8-hydroxyquinolinato)aluminum (Alq3), Bis(2-methyl-8-quinolinolato-N1,08)-(1,1′-Biphenyl-4-olato)aluminum (BAlq), 1,3,5-tri[(3-pyridyl)-2,4,6-tris(3′-(pyridin-3-yl) biphenyl-3-yl)-1,3,5-triazine, 2-(4-(N-phen-3-yl]benzene, phenylbenzimidazol-1-yl)phenyl)-9,10-dinaphthylanthracene, 1,3,5-Tri (1-phenyl-1H-benzo[d]imidazol-2-yl)benzene (TPBi), 4,7-Diphenyl-1,10-phenanthroline (Bphen), 3-(Biphenyl-4-yl)-4-phenyl-5-tert-butylphenyl-1,2,4-triazole (TAZ), 4-(Naphthalen-1-yl)-3,5-diphenyl-4H-1,2,4-triazole (NTAZ), 2-(Biphenyl-4-yl)-5-(4-tert-butylphenyl)-1,3,4-oxadiazole (tBu-PBD), berylliumbis(benzoquinolin-10-olate)(Bebq2), 9,10-di(naphthalen-2-yl) anthracene (AND), 1,3-Bis[3,5-di(pyridin-3-yl)phenyl]benzene (BmPyPhB), or a combination thereof, but the present disclosure is not limited thereto.

In one or more embodiments, the electron functional layer EFL (e.g. the electron transport layer ETL in the electron functional layer EFL) may include a metal-containing material in addition to one or more of the afore-described materials. For example, the metal-containing material may include a Li complex. The Li complex may further include, for example, a compound ET-D1 (LiQ) or ET-D2.

In one or more embodiments, the electron functional layer EFL may include an electron injection layer EIL configured to allow easy injection of an electron from the second electrode EL2. The electron injection layer may make direct contact with the second electrode.

The electron functional layer EFL may have a single layer including (e.g., consisting of) a single material, a single layer including (e.g., consisting of) a plurality of different materials, or a multilayer structure having a plurality of layers including (e.g., consisting of) a plurality of different materials.

The electron functional layer EFL (e.g., electron injection layer EIL) may include an alkaline earth metal, a rare earth metal, an alkali metal, an alkaline earth metal-containing compound, a rare earth metal-containing compound, an alkali metal-containing compound, an alkaline earth metal complex, a rare earth metal complex, an alkali metal complex, or a combination thereof, or further include an organic material (e.g. a compound represented by Formula EM-2 or Formula EM-3).

The alkaline earth metal may include Mg, Ca, Sr, Ba, or any combination thereof.

The rare earth metal may include Sc, Y, Ce, Tb, Yb, Gd, or a combination thereof.

The alkali metal may include Li, Na, K, Rb, Cs, or a combination thereof.

In one or more embodiments, the electron functional layer EFL may include a halogenated metal, such as LiF, NaCl, CsF, RbCl, RbI, Cul, and/or KI, a lanthanide metal such as Yb, or a co-deposition material of a halogenated metal and a lanthanide metal. For example, the co-deposition material of a halogenated metal and a lanthanide metal may include KI:Yb, RbI:Yb, and/or LiF:Yb. In one or more embodiments, a metal oxide, such as Li₂O and/or BaO, 8-hydroxyl-Lithium quinolinolate (LiQ), and/or the like may be used for the electron functional layer EFL, but embodiments of the present disclosure are not limited thereto. In one or more embodiments, the electron functional layer EFL may also be consisting of a mixture material of an electron transport material and an insulating organo-metal salt. The insulating organo-metal salt may be a material having an energy band gap of about 4 eV or greater. For example, the insulating organo-metal salt may include, for example, a metal acetate, a metal benzoate, a metal acetoacetate, a metal acetylacetonate, and/or a metal stearate.

In one or more embodiments, the electron functional layer EFL may include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to one or more of the materials described above, but embodiments of the present disclosure are not limited thereto.

Compounds of the electron functional layer EFL may be included in at least one of the electron injection layer EIL, the electron transport layer ETL, or the hole blocking layer HBL in the electron functional layer EFL.

If (e.g., when) the electron functional layer EFL may include an electron transport layer ETL, the electron transport layer ETL may have a thickness of about 100 Å to about 1000 Å, such as about 150 Å to 500 Å. If (e.g., when) the thickness of the electron transport layer ETL satisfies the range described above, satisfactory level of electron transport properties may be obtained without a substantial increase in a driving voltage.

If (e.g., when) the electron functional layer EFL includes an electron injection layer EIL, the electron injection layer EIL may have a thickness of about 1 Å to about 100 Å, such as about 3 Å to about 90 Å. If (e.g., when) the thickness of the electron injection layer EIL satisfies the range described above, satisfactory level of electron injection properties may be obtained without a substantial increase in a driving voltage.

In one or more embodiments, a first capping layer may be arranged outside of (e.g., on) the first electrode EL1, and/or a second capping layer may be arranged outside of (e.g., on) the second electrode EL2.

In one or more embodiments, light generated from the light-emitting layer of the light-emitting diode ED may be extracted toward the outside through the first electrode EL1, which is a semi-transmissive electrode or a transmissive electrode, and the first capping layer; in one or more embodiments, light generated from the light-emitting layer of the light-emitting diode ED may be extracted toward the outside through the second electrode EL2, which is a semi-transmissive electrode or a transmissive electrode, and the second capping layer.

In one or more embodiments, the capping layer CPL may independently be an organic capping layer including an organic material, an inorganic capping layer including an inorganic material, or a composite capping layer including an organic material and an inorganic material.

In one or more embodiments, the capping layer CPL may be an organic layer or an inorganic layer. For example, if (e.g., when) the capping layer CPL includes an inorganic material, the inorganic material may include an alkali metal compound, such as LiF, an alkaline earth metal compound, such as MgF₂, SiON, SiNₓ, SiO_{y}, and/or the like. For example, if (e.g., when) the capping layer CPL includes an organic material, the organic material may include an amine compound, such as a monoamine and/or a diamine. For example, in one or more embodiments, the organic material may include TPD, α-NPD, β-NPB, m-MTDATA, N4,N4,N4′,N4′-tetra (biphenyl-4-yl) biphenyl-4,4′-diamine (TPD15), 4,4′4″-Tris(carbazol-9-yl)triphenylamine (TCTA), and/or the like. However, embodiments of the present disclosure are not limited thereto, for example, in one or more embodiments, the capping layer CPL may include Alq₃, CuPc, an epoxy resin, or an acrylate, such as a methacrylate.

The capping layer CPL may include at least one of (e.g., selected from among) Compound CP1 through Compound CP4, but the present disclosure is not limited thereto.

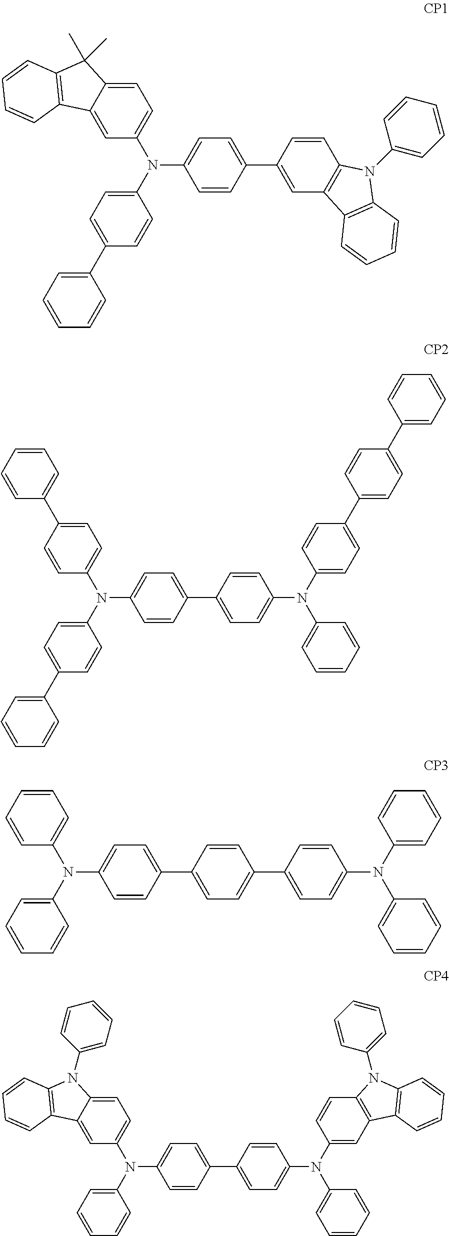 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

In one or more embodiments, the capping layer CPL may have a refractive index of 1.6 or more, but the present disclosure is not limited thereto. For example, the refractive index of the capping layer CPL with respect to light in a wavelength range of 550 nm to 660 nm may be 1.6 or more, 1.8 or more, or 2.0 or more.

A display device 200′ may further include a light controlling layer CCL arranged on the display device layer EDL.

The light controlling layer CCL may include a plurality of light controlling parts. The light controlling parts may be separated from one another and a partition pattern BMP may be arranged between the light controlling parts. Nonetheless, embodiments of the present disclosure are not limited thereto, and for example, in one or more embodiments, edges of the light controlling parts may overlap with one another or edges of the light controlling parts may overlap with the partition pattern.

The light controlling layer CCL may include a first through a third light controlling parts overlapping with the first through the third light-emitting diodes, respectively.

At least one of the first through the third light controlling parts may transform a wavelength of incident light (e.g. blue light) and then emit light of different color (e.g. red light or green light). In addition, at least one of the first through the third light controlling parts may be to transmit incident light (e.g. blue light) without transforming its wavelength.

In one or more embodiments, at least one of the first through the third light controlling parts may include a light converter, such as a quantum dot or a phosphor. The light converter may transform the wavelength of light provided and then emit the transformed (converted) light. The first through the third light controlling parts may each further include a scatter and a base resin configured to disperse the scatter.

In one or more embodiments, the light controlling layer CCL may further include a barrier layer configured to prevent or reduce penetration of moisture and/or oxygen.

An electronic device according to another aspect includes a light emitting diode, the light-emitting diode including a first electrode, a second electrode arranged on the first electrode, and stack units arranged between the first electrode and the second electrode, vertically laminated to form a plurality of layers, and including a plurality of light-emission layers EML on each layer, wherein one or more light-emission layers among the plurality of light-emission layers EML included in at least an uppermost stack unit among the laminated stack units are thermally activated delayed fluorescence light-emission layers configured to emit thermally activated delayed fluorescence, and wherein at least one stack unit below the uppermost stack unit includes one or more types of a phosphorescence light-emission layer and a fluorescence light-emission layer.

In one or more embodiments of the present disclosure, the electronic device may include a display device, a processor configured to control the display device, a memory configured to store data necessary for operation of the display device and the processor, and a power module configured to generate or supply power.

An electronic device according to the above embodiment may be applicable to various electronic devices. Aan electronic device according to one or more embodiments may include an electronic device described below, and further include a module or a device having an additional function in addition to the electronic device.

FIG. 5 is a block diagram of an electronic device according to one or more embodiments. Referring to FIG. 5, an electronic device 210 according to one or more embodiments may include a display module 211, a processor 212, a memory 213, and a power module 214. The electronic device 210 may further include an input module 215, an output module 216, and/or a communication module 217.

The electronic device 210 may be configured to output various information in a form of an image through the display module 211. In the case that the processor 212 operates an application stored in the memory 213, the application may be configured to provide image information to a user through the display module 211. The power module 214 may include a power supply module, such as a power adaptor or a batter device, and a power conversion module configured to convert power supplied from the power supply module to generate power necessary for operation of the electronic device 210. The input module 215 may provide input information to the processor 212 and/or the power module 211. The output module 216 (or non-image output module) may be configured to receive acoustic, haptic, or light-emission information in addition to image provided from the processor to provide the information to a user. The communication module 217 is a module configured to transmit and receive information between the electronic device 210 and an external device and include a receiver and a transmitter.

At least one of the above-described components of the electronic device 210 may be included within the electronic device according to the above-described embodiments. Additionally, certain individual modules included functionally within a single module may be provided within the display device while other individual modules may be provided outside the electronic device. For instance, the display device may include the display module 211, and the processor 212, memory 213, and power module 214 may be provided as other devices within the electronic device 210 but not within the display device.

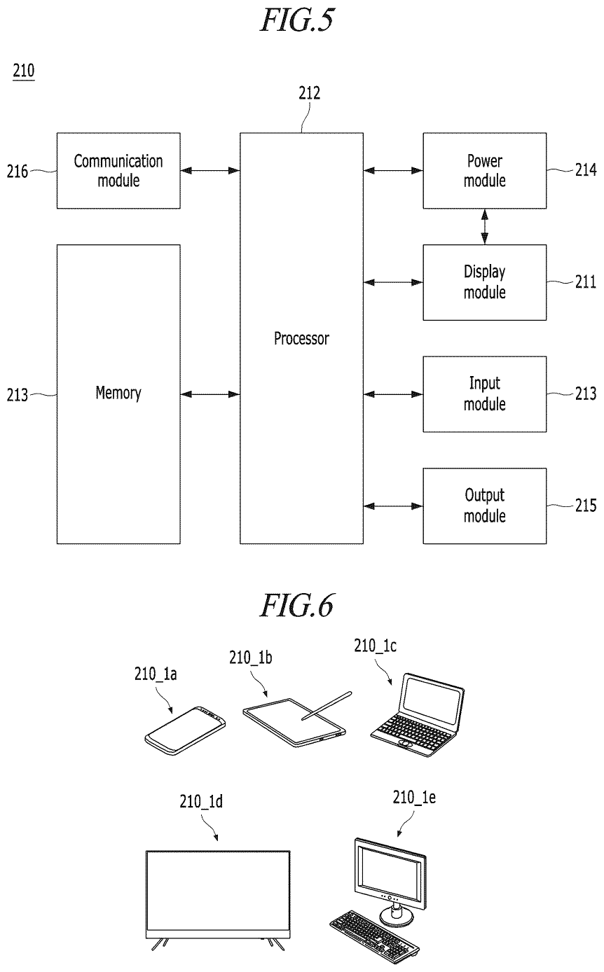

FIG. 6 through FIG. 8 are schematic diagrams of electronic devices according to various embodiments. FIG. 6 through FIG. 8 illustrate examples of various electronic devices applied with electronic devices according to embodiments.

As examples of an electronic device, FIG. 6 illustrate a smartphone 210_1A, a tablet PC 210_1B, a laptop 210_1C, a TV 210_1D, and a desktop monitor 210_1E.

A smartphone 210_1A may include an input module, such as a touch sensor, and a communication module in addition to a display module 211. A smartphone 210_1A may be configured to process information received from the communication module or other input modules to display information through the display module of the electronic device.

Similar to the smartphone 210_1A, a tablet PC 210_1B, a laptop 210_1C, a TV 210_1D, a desktop monitor 210_1E may also include a display module and an input module, and in some embodiments, a communication module may be further included.

FIG. 7 illustrates an example in which an electronic device including a display module is applied to a wearable electronic device. Examples of a wearable electronic device may be smart glasses 210_2A, a head-mounted display 210_2B, or a smart watch 210_2C.

Smart glasses 210_2A and a head-mounted display 210_2B may include a display module configured to emit a display image and a reflector configured to reflect a display screen towards eyes of a user. Accordingly, an image of virtual reality or augmented reality may be provided to a user.

A smart watch 210_2C may include a biometric sensor as an input device and be configured to provide biometric information recognized through the biometric sensor to a user through a display module.

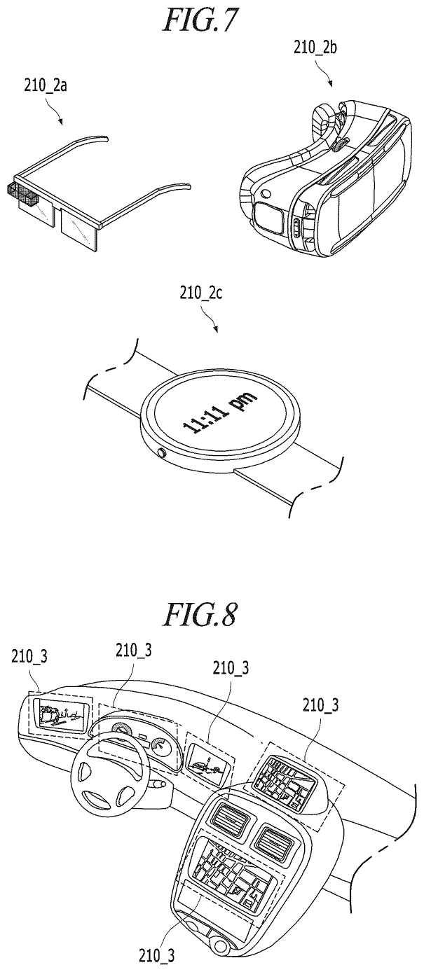

FIG. 8 illustrates an example in which an electronic device including a display module is applied to a vehicle. For example, an electronic device 210_3 may be applied to, for example, a vehicle instrument panel, center fascia, center information display (CID) arranged on a dashboard of a vehicle, or a room mirror display replacing a side mirror.

Although it is not illustrated, an electronic device applicable with an electronic device according to one or more embodiments may include devices mainly for displaying an image and devices displaying information through a display module. In the case that a display module allows penetration of light, an electronic device according to one or more embodiments may be applicable to an electronic device, such as a smart window, or a transparent electronic device displaying an image along with a background. For example, an electronic device according to one or more embodiments may be applicable to one or more suitable electronic devices, such as a plane panel display, a curved display, a television, a billboard, a computer monitor, a medical monitor, a head mounted display (HMD), a light for indoor light, an outdoor light, signal light, a wearable device, a foldable device, a rollable device, a bendable device, a flexible device, a curved device, an electronic organizer, an electronic book, a portable multimedia player (PMP), a personal digital assistance (PDA), a laser printer, a telephone, a portable phone, a tablet PC, a portable terminal, a laptop computer, a digital camera, a viewfinder, a camcorder, a 3D display, a virtual reality display, an augmented reality display, a video wall including multiple displays tiled together, a vehicle, an outdoor electronic device, a theater screen, a stadium screen, a billboard, a screen, a signboard, and a game console, and various home appliances displaying information through a display module, such as a refrigerator, a washing machine, a dryer, an air conditioner, or a robot vacuum cleaner. However, types of an electronic device according to one or more embodiments are not limited to the above examples, and an electronic device according to one or more embodiments of the present disclosure may be applicable to various undescribed electronic devices.

Hereinafter, embodiments of the present disclosure and comparative examples are described. A light-emitting diode according to one or more embodiments will be described in detail. In addition, the following embodiment is merely an embodiment for understanding of the present disclosure, and a scope of the present disclosure is not limited thereto.

Hereinafter, the present disclosure will be described with reference to embodiments in detail.

### EXPERIMENTAL EXAMPLE

### Comparative Example 1. Manufacture of a Tandem Light-Emitting Diode

As a first electrode, a glass substrate (product of Corning Inc.) with formation of an ITO electrode with 15 ohms per square centimeter (Ω/cm²)(1200 Å) was cut into a size of 50 millimeters (mm)×50 mm×0.5 mm, washed by ultrasonic waves with isopropyl alcohol and pure water for 5 minutes each, cleaned by irradiating ultraviolet rays for 30 minutes and then exposing to ozone, and installed in a vacuum deposition device.

HT1 and F4-TCNQ were simultaneously deposited with a weight ratio of 98:2 on an ITO/Ag/ITO anode of the glass substrate to form a first hole injection layer with a thickness of 100 Å and on the hole injection layer to form a first hole transport layer with a thickness of HT1 200 Å.

Then, CBP as a red host and Ir(piq)₃ as a red dopant were simultaneously deposited with a weight ratio of 97:3 on the first hole transport layer in a red sub-pixel region to form a first red light-emission layer with a thickness of 450 Å. Subsequently, CBP as a green host and Ir(ppy)₃ as a green dopant were simultaneously deposited with a weight ratio of 92:8 on the first hole transport layer in a green sub-pixel region to form a first green light-emission layer with a thickness of 350 Å. Subsequently, BH as a blue host and BH as a blue dopant were simultaneously deposited with a weight ratio of 99:1 on the first hole transport layer in a blue sub-pixel region to form a first blue light-emission layer with a thickness of 200 Å. Accordingly, a first light-emission layer including the first red light-emission layer, the first green light-emission layer and the first blue light-emission layer was formed.

BF1 was deposited to a thickness of 50 Å on an entire upper portion of the first light-emission layer to form a first buffer layer. Subsequently, ET-1 was deposited to a thickness of 150 Å on an upper portion of the first buffer layer to form a first electron transport layer. Accordingly, a first light-emitting unit including the first hole injection layer, the first hole transport layer, the first light-emission layer, the buffer layer and the first electron transport layer was formed.

On the first electron transport layer, Bphen and Li were simultaneously deposited with a weight ratio of 98:2 to a thickness of 100 Å as an n-type electric charge generation layer, and HT1 and F4-TCNQ were simultaneously deposited with a weight ratio of 95:5 to a thickness of 100 Å as a p-type electric charge generation layer. Subsequently, HT1 alone was deposited to a thickness of 400 Å to form a second hole transport layer.

Thereafter, CBP as a red host and Ir(piq)₃ as a red dopant were simultaneously deposited with a weight ratio of 97:3 on the p-type electric charge generation layer in a red sub-pixel region to form a second red light-emission layer with a thickness of 450 Å. Subsequently, CBP as a green host and Ir(ppy)₃ as a green dopant were simultaneously deposited with a weight ratio of 92:8 on the second hole transport layer in a green sub-pixel region to form a second green light-emission layer with a thickness of 350 Å. Then, BH as a blue host and BD as a blue dopant were simultaneously deposited with a weight ratio of 99:1 on the second hole transport layer in a blue sub-pixel region to form a second blue light-emission layer with a thickness of 200 Å. Accordingly, the second red light-emission layer, a second light-emission layer including the second green light-emission layer and the second blue light-emission layer was formed.

BF1 was deposited to a thickness of 50 Å to form a second buffer layer entirely on an upper portion of the second light-emission layer. Subsequently, ET-1 was deposited on an upper portion of the second buffer layer to form a second electron transport layer with a thickness of 300 Å. Accordingly, a second light-emission unit including the hole auxiliary layer, the second light-emission layer, the second buffer layer and the second electron transport layer was formed.

Ag:Mg was deposited to a thickness of 120 Å on the second electron transport layer to form a cathode. Accordingly, a light-emitting diode was manufactured.

### Embodiment 1-7. Manufacture of a Tandem Light-Emitting Diode

In Embodiment 1 through Embodiment 7 applied with a TADF on a first light-emission layer and a second light-emission layer, a light-emitting diode was manufactured in the same method except for red, green, and blue TADF light-emission layers.

### 1) Manufacture of Red TADF Light-Emission Layer

CBP as a red host, Ir(piq)₃ as a red dopant, and a red TADF emitter (RTD) compound were simultaneously deposited with a weight ratio of 96:3:1 in a red sub-pixel region to form a red TADF light-emission layer with a thickness of 450 Å.

### 2) Manufacture of a Green TADF Light-Emission Layer

CBP as a green host, Ir(ppy)₃ as a green dopant, and a green TADF emitter (GTD) compound were simultaneously deposited with a weight ratio of 91:8:1 in a green sub-pixel region to form a green TADF light-emission layer with a thickness of 350 Å.

### 3) Manufacture of a Blue TADF Light-Emission Layer

A first host ET-1, a second host HT-1, BD-1 as a blue phosphorescence dopant, and a blue TADF emitter D-01 compound was co-deposited with a weight ratio of 55:34:10:1 in a blue sub-pixel region to form a light-emission layer with a thickness of 400 Å.

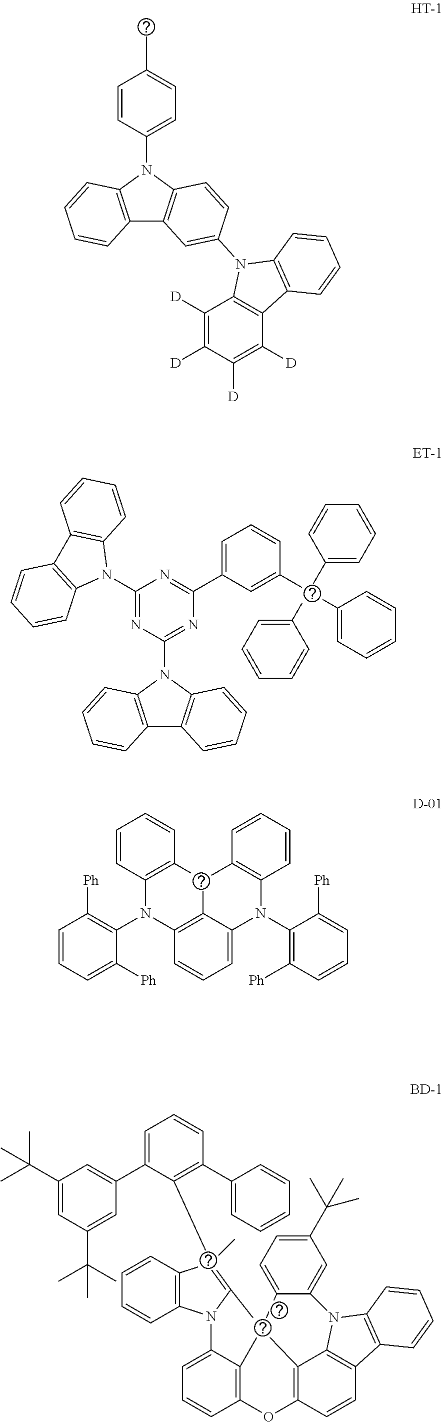

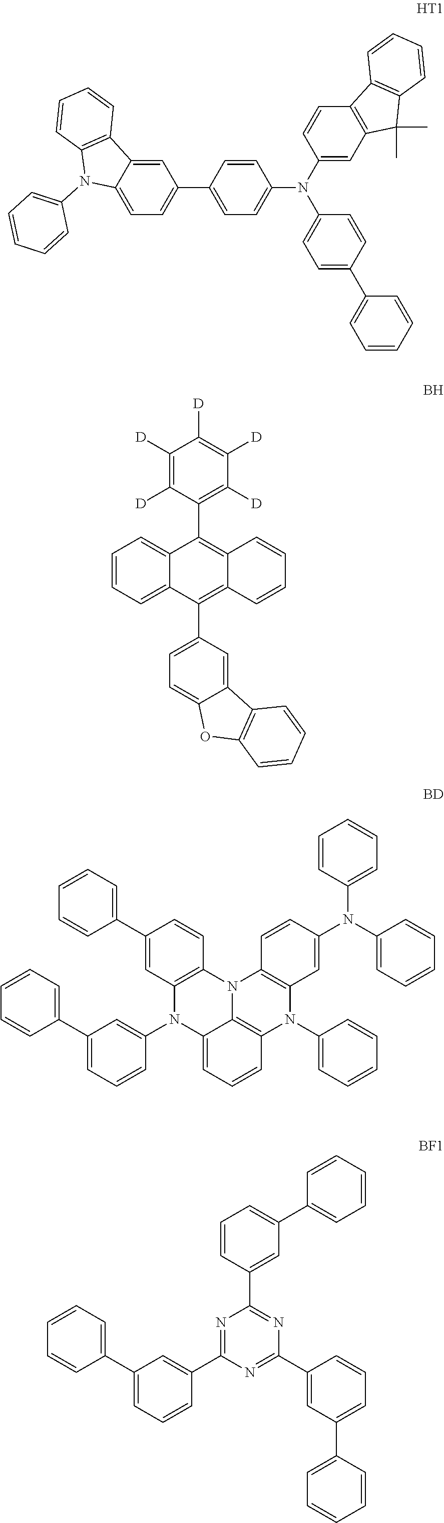 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; [2H]c1c([2H])c([2H])c(-c2c3ccccc3c(-c3ccc4oc5ccccc5c4c3)c3ccccc23)c([2H])c1[2H] ; c1ccc(-c2cccc(N3c4cc(-c5ccccc5)ccc4N4c5ccc(N(c6ccccc6)c6ccccc6)cc5N(c5ccccc5)c5cccc3c54)c2)cc1 ; c1ccc(-c2cccc(-c3nc(-c4cccc(-c5ccccc5)c4)nc(-c4cccc(-c5ccccc5)c4)n3)c2)cc1]

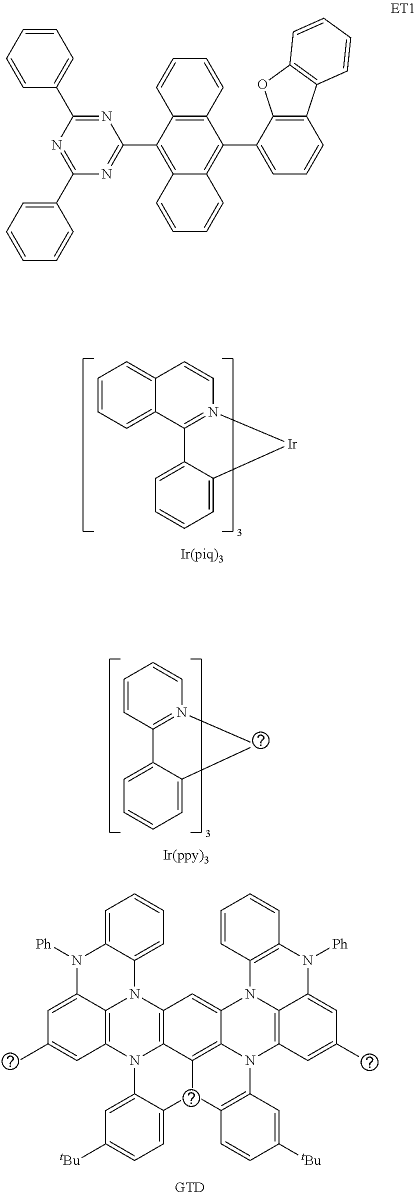

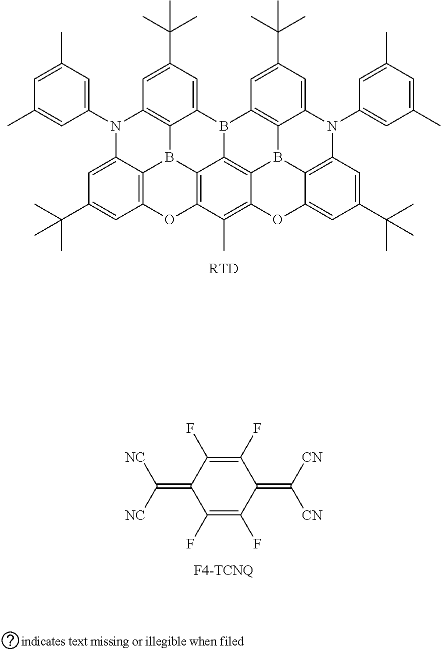

### Comparative Manufacture Example 1

A tandem light-emitting diode including a blue light-emission layer in a first stack unit and a second stack unit was manufactured. It was manufactured by the same method as Comparative Example 1 except for including a blue light-emission layer only.

### Manufacture Example 1-1

The same method as Comparative Manufacture Example 1 was used except for including a blue TADF light-emission layer in the second stack unit.

### Manufacture Example 1-2

The same method as Comparative Manufacture Example 1 was used except for including a blue TADF light-emission layer in the first stack unit.

### Manufacture Example 1-3

The same method as Comparative Manufacture Example 1 was used except for including a blue TADF light-emission layer in the first stack unit and the second stack unit.

### Comparative Manufacture Example 2

A tandem light-emitting diode including a green light-emission layer in a first stack unit and a second stack unit was manufactured. The same method as Comparative Example 1 was used except for including a green light-emission layer only.

### Manufacture Example 2-1

The same method as Comparative Manufacture Example 2 was used except for including a green TADF light-emission layer in the second stack unit.

### Manufacture Example 2-3

The same method as Comparative Manufacture Example 2 was used except for including a green TADF light-emission layer in the first stack unit and the second stack unit.

### Comparative Manufacture Example 3

A tandem light-emitting diode including a red light-emission layer in a first stack unit and a second stack unit was manufactured. The same method as Comparative Example 1 was used except for including a red light-emission layer only.

### Manufacture Example 3-1

The same method as Comparative Manufacture Example 3 was used except for including a red TADF light-emission layer in the second stack unit.

### Manufacture Example 3-3

The same method as Comparative Manufacture Example 3 was used except for including a red TADF light-emission layer in the first stack unit and the second stack unit.

### Embodiment 2

The same method as Embodiment 1 was used except for including a red phosphorescence light-emission layer, a green phosphorescence light-emission layer, a blue fluorescence light-emission layer in a first stack unit, and a red phosphorescence light-emission layer, a green TADF light-emission layer, and a blue fluorescence light-emission layer in a second stack unit.

### Embodiment 3

The same method as Embodiment 1 was used except for including a red phosphorescence light-emission layer, a green phosphorescence light-emission layer, and a blue fluorescence light-emission layer in a first stack unit, and a red phosphorescence light-emission layer, a green TADF light-emission layer, and a blue TADF light-emission layer in a second stack unit.

### Embodiment 4

The same method as Embodiment 1 was used except for including a red phosphorescence light-emission layer in the first stack unit, and a red TADF light-emission layer, a green phosphorescence light-emission layer, and a blue fluorescence light-emission layer in the second stack unit.

### Embodiment 5

The same method as Embodiment 1 was used except for including a red phosphorescence light-emission layer, a green phosphorescence light-emission layer, and a blue fluorescence light-emission layer in the first stack unit, and a red TADF light-emission layer, a green phosphorescence light-emission layer, and a blue TADF light-emission layer in the second stack unit.

### Embodiment 6

The same method as Embodiment 1 was used except for including a red phosphorescence light-emission layer, a green phosphorescence light-emission layer, and a blue fluorescence light-emission layer in the first stack unit, and a red TADF light-emission layer, a green TADF light-emission layer, and a blue fluorescence light-emission layer in the second stack unit.

### Embodiment 7

The same method as Embodiment 1 was used except for including a red phosphorescence light-emission layer, a green phosphorescence light-emission layer, and a blue fluorescence light-emission layer in the first stack unit, and a red TADF light-emission layer, a green TADF light-emission layer, and a blue TADF light-emission layer in the stack unit.

In Embodiment 8 through Embodiment 13, a light-emitting diode was manufactured in the same method as Embodiment 1 except for having a thickness of a light-emission layer of the second stack unit different from a thickness of a light-emission layer of the first stack unit

### Embodiment 8

The same method as Embodiment 1 was used except for including a red phosphorescence light-emission layer, a green phosphorescence light-emission layer, and a blue fluorescence light-emission layer in the first stack unit, and a red TADF light-emission layer, a green TADF light-emission layer, and a blue TADF light-emission layer in the second stack unit thicker than a thickness of corresponding layers in the first stack unit by 50 Å.

### Embodiment 9

The same method as Embodiment 1 was used except for including a red phosphorescence light-emission layer, a green phosphorescence light-emission layer, and a blue fluorescence light-emission layer in the first stack unit, and having a respective thickness of a red TADF light-emission layer, a green TADF light-emission layer, and a blue TADF light-emission layer in the second stack unit thicker than a thickness of the first stack unit by 100 Å.

### Embodiment 10

The same method as Embodiment 1 was used except for including a red phosphorescence light-emission layer, a green phosphorescence light-emission layer, and a blue fluorescence light-emission layer in the first stack unit, and having a respective thickness of a red TADF light-emission layer, a green TADF light-emission layer, and a blue TADF light-emission layer in the second stack unit thicker than a thickness of the first stack unit by 150 Å.

### Embodiment 11

The same method as Embodiment 1 was used except for including a red phosphorescence light-emission layer, a green phosphorescence light-emission layer, and a blue fluorescence light-emission layer in the first stack unit, and having a respective thickness of a red TADF light-emission layer, a green TADF light-emission layer, and a blue TADF light-emission layer in the second stack unit thicker than a thickness of the first stack unit by 200 Å.

### Embodiment 12

The same method as Embodiment 1 was used except for including a red phosphorescence light-emission layer, a green phosphorescence light-emission layer, and a blue fluorescence light-emission layer in the first stack unit, and having a respective thickness of a red TADF light-emission layer, a green TADF light-emission layer, and a blue TADF light-emission layer in the second stack unit thicker than a thickness of the first stack unit by 250 Å.

### Embodiment 13

The same method as Embodiment 1 was used except for including a red phosphorescence light-emission layer, a green phosphorescence light-emission layer, and blue fluorescence light-emission layer in the first stack unit, and having a respective thickness of a red TADF light-emission layer, a green TADF light-emission layer, and a blue TADF light-emission layer in the second stack unit thicker than a thickness of the first stack unit by 300 Å.

### Results

### Experimental Example 1. Verification of Light-Emitting Diode Properties

According to a manufacture example of the present disclosure, light-emitting properties of Manufacture Example 1-1 through Manufacture Example 1-3, Manufacture Example 2-1, Manufacture Example 2-3, Manufacture Example 3-1, Manufacture Example 3-3, and Comparative Example 1 through Comparative Example 3 were evaluated, and its results were shown in Table 1.

Diode property evaluations were performed by measurements of a current efficiency (Cd/A/y) under a current density of 1000 candelas per square meter (cd/m2), and a lifespan (T95) using Keithley MU 236 and a luminance meter PR650 for each light-emission color. A time taken for the initial luminance to reach 95% was measured for the lifespan (T95), and a relative lifespan was calculated based on Comparative Example 1. The respective results were shown.

Referring to Table 1, in comparison to Comparative Manufacture Example 1, a high current efficiency properties were shown when a TADF emitter is included in a light-emission layer of the first stack unit and/or a light-emission layer of the second stack unit. However, when both light-emission layer of the first stack unit and light-emission layer of the second stack unit included a TADF emitter, current efficiency was relatively increased, but the lifespan was decreased by half. When only the second light-emission layer included a TADF emitter, a current efficiency increased, and the lifespan was maintained at a high level.

TABLE 1

| | | | Light-emission Layer EML | | Diode Property | | |
|---|---|---|---|---|---|---|---|
| | | | First | Second | Current | | |
| | | Tandem Light- | stack | stack | Efficiency | | |
| | NO. | emitting Diode | unit | unit | (Cd/A/y) | T95 (%) | Note |
| Blue | Comparative | Fluores- | Fluores- | Fluores- | 100% | 100% | |
| | Manufacture | cence/ | cence B | cence B | | | |
| | Example 1 | Fluores- | | | | | |
| | | cence | | | | | |
| | Manufacture | Fluores- | Fluores- | TADF B | 170% | 80% | Optimum |
| | Example 1-1 | cence/ | cence B | | | | efficiency |
| | | TADF | | | | | and lifespan |
| | Manufacture | TADF/ | TADF B | Fluores- | 154% | 70% | |
| | Example 1-2 | Fluores- | | cence B | | | |
| | | cence | | | | | |
| | Manufacture | TADF/ | TADF B | TADF B | 200% | 50% | Maximum |
| | Example 1-3 | TADF | | | | | efficiency, |
| | | | | | | | minimum |
| | | | | | | | lifespan |
| Green | Comparative | Phospho- | Phospho- | Phospho- | 100% | 100% | |
| | Example 2 | rescence/ | rescence G | rescence G | | | |
| | | Phospho- | | | | | |
| | | rescence | | | | | |
| | Manufacture | Phospho- | Phospho- | TADF G | 140% | 83% | Optimum |
| | Example 2-1 | rescence/ | rescence G | | | | efficiency |
| | | TADF | | | | | and lifespan |
| | Manufacture | TADF/ | TADF G | TADF G | 165% | 55% | Maximum |
| | Example 2-3 | TADF | | | | | efficiency, |
| | | | | | | | minimum |
| | | | | | | | lifespan |
| Red | Comparative | Phospho- | Phospho- | Phospho- | 100% | 100% | |
| | Example 3 | rescence/ | rescence R | rescence R | | | |
| | | Phospho- | | | | | |
| | | rescence | | | | | |
| | Manufacture | Phospho- | Phospho- | TADF R | 135% | 87% | Optimum |
| | Example 3-1 | rescence/ | rescence R | | | | efficiency |
| | | TADF | | | | | and lifespan |
| | Manufacture | TADF/ | TADF R | TADF R | 157% | 58% | Maximum |
| | Example 3-3 | TADF | | | | | efficiency, |
| | | | | | | | minimum |
| | | | | | | | lifespan |

### Experimental Example 2. Verification of Current Efficiency Properties of Light-emitting Diode

In one or more embodiments, current efficiency of Embodiment 1 through Embodiment 7 and Comparative Example 1 was measured and shown in Table 2. Referring to Table 2, in Embodiment 1, in which a TADF emitter is included in a blue light-emission layer of one type of second stack unit, current efficiency of the light-emitting diode was improved to 120% in comparison to Comparative Example 1. The current efficiency is much improved from a case where a TADF emitter is included in a green light-emission layer (107%) or a red light-emission layer (105%) of the second stack unit.

In addition, when a light-emitting diode is manufactured by including a TADF emitter in two types of second stack unit, current efficiency of a light-emitting diode relatively decreased in an order of a green TADF light-emission layer and a blue TADF light-emission layer (130%), a red TADF light-emission layer and a blue TADF light-emission layer (126%), a red TADF light-emission layer and a green TADF light-emission layer (112%).

In addition, Embodiment 7, in which all three types of light-emission layer in the second stack unit included a TADF emitter, showed most improvement of current efficiency of a light-emitting diode by 150% among light-emitting diodes.

TABLE 2

| | | | | | | | White |
|---|---|---|---|---|---|---|---|
| | REML | | GEML | | BEML | | Diode |
| | First | Second | First | Second | First | Second | Property |
| | stack | stack | stack | stack | stack | stack | Current |
| No. | unit | unit | unit | unit | unit | unit | Efficiency |
| Comparative | Phospho- | Phospho- | Phospho- | Phospho- | Fluores- | Fluores- | 100% |
| Example 1 | rescence | rescence | rescence | rescence | cence | cence | |
| Embodiment | Phospho- | Phospho- | Phospho- | Phospho- | Fluores- | TADF | 120% |
| 1 | rescence | rescence | rescence | rescence | cence | | |
| Embodiment | Phospho- | Phospho- | Phospho- | TADF | Fluores- | Fluores- | 107% |
| 2 | rescence | rescence | rescence | | cence | cence | |
| Embodiment | Phospho- | Phospho- | Phospho- | TADF | Fluores- | TADF | 130% |
| 3 | rescence | rescence | rescence | | cence | | |
| Embodiment | Phospho- | TADF | Phospho- | Phospho- | Fluores- | Fluores- | 105% |
| 4 | rescence | | rescence | rescence | cence | cence | |
| Embodiment | Phospho- | TADF | Phospho- | Phospho- | Fluores- | TADF | 126% |
| 5 | rescence | | rescence | rescence | cence | | |
| Embodiment | Phospho- | TADF | Phospho- | TADF | Fluores- | Fluores- | 112% |
| 6 | rescence | | rescence | | cence | cence | |
| Embodiment | Phospho- | TADF | Phospho- | TADF | Fluores- | TADF | 150% |
| 7 | rescence | | rescence | | cence | | |

### Experimental Example 3. Current Efficiency Property Verification of Light-Emitting Diode Based on Thickness of Second Stack Unit

In order to verify current efficiency properties based on a thickness of the second stack unit, current efficiency properties of Embodiment 8 through Embodiment 13 of the present disclosure and Comparative Example 1 were measured and shown in Table 3. Current efficiency was measured while a conventionally available stack unit was used as a first stack unit and a thickness of the second stack unit was changed.

For example, Embodiment 8 was a case where a thickness of second stack unit was thicker than a thickness of the first stack unit by 50 Å. As a result of the experiment, the thicker the thickness of the second stack unit was than the thickness of the first stack unit, the more current efficiency was improved. When the thickness of the second stack unit was thicker than the thickness of the first stack unit by 200 Å, the highest current efficiency (150%) was shown.

TABLE 3

| | | | | | | | White |
|---|---|---|---|---|---|---|---|
| | REML | | GEML | | BEML | | Diode |
| | First | Second | First | Second | First | Second | Property |
| | stack | stack | stack | stack | stack | stack | Current |
| NO. | unit | unit | unit | unit | unit | unit | Efficiency |
| Comparative | Phospho- | Phospho- | Phospho- | Phospho- | Fluores- | Fluores- | 100% |
| Example | rescence | rescence | rescence | rescence | cence | cence | |
| Embodiment | Phospho- | Film | Phospho- | Film | Fluores- | Film | 120% |
| 8 | rescence | Thickness + | rescence | Thickness + | cence | Thickness + | |
| | | 50 Å than | | 50 Å than | | 50 Å than | |
| | | TADF 1st- | | TADF 1st- | | TADF 1st- | |
| | | stack | | stack | | stack | |
| Embodiment | Phospho- | Film | Phospho- | Film | Fluores- | Film | 130% |
| 9 | rescence | Thickness + | rescence | Thickness + | cence | Thickness + | |
| | | 100 Å than | | 100 Å than | | 100 Å than | |
| | | TADF 1st- | | TADF 1st- | | TADF 1st- | |
| | | stack | | stack | | stack | |
| Embodiment | Phospho- | Film | Phospho- | Film | Fluores- | Film | 145% |
| 10 | rescence | Thickness + | rescence | Thickness + | cence | Thickness + | |
| | | 150 Å than | | 150 Å than | | 150 Å than | |
| | | TADF 1st- | | TADF 1st- | | TADF 1st- | |
| | | stack | | stack | | stack | |
| Embodiment | Phospho- | Film | Phospho- | Film | Fluores- | Film | 150% |
| 11 | rescence | Thickness + | rescence | Thickness + | cence | Thickness + | |
| | | 200 Å than | | 200 Å than | | 200 Å than | |
| | | TADF 1st- | | TADF 1st- | | TADF 1st- | |
| | | stack | | stack | | stack | |
| Embodiment | Phospho- | Film | Phospho- | Film | Fluores- | Film | 135% |
| 12 | rescence | Thickness + | rescence | Thickness + | cence | Thickness + | |
| | | 250 Å than | | 250 Å than | | 250 Å than | |
| | | TADF 1st- | | TADF 1st- | | TADF 1st- | |
| | | stack | | stack | | stack | |
| Embodiment | Phospho- | Film | Phospho- | Film | Fluores- | Film | 120% |
| 13 | rescence | Thickness + | rescence | Thickness + | cence | Thickness + | |
| | | 300 Å than | | 300 Å than | | 300 Å than | |
| | | TADF 1st- | | TADF 1st- | | TADF 1st- | |
| | | stack | | stack | | stack | |

While certain embodiments of the present disclosure have been described above, anyone ordinarily skilled in the art to which the present disclosure pertains shall appreciate that there may be a variety of modifications and permutations of the present disclosure without departing from the technical ideas and scopes of the present disclosure that are defined in the appended claims. Therefore, the technical scope of the present disclosure should be interpreted by the scope of the claims and equivalents thereof, instead of being restricted the disclosed description in Detailed Description.

What is claimed is:

1. A light-emitting diode comprising:
a first electrode;
a second electrode arranged on the first electrode; and
stack units arranged between the first electrode and the second electrode, vertically laminated to form a plurality of layers, and comprising a plurality of light-emission layers on each layer,
wherein one or more light-emission layers among the plurality of light-emission layers in an uppermost stack unit among the laminated stack units are thermally activated delayed fluorescence light-emission layers configured to emit thermally activated delayed fluorescence, and
wherein at least one stack unit below the uppermost stack unit comprises at least one of a phosphorescence light-emission layer or a fluorescence light-emission layer.

2. The light-emitting diode of claim 1,
wherein at least one of the thermally activated delayed fluorescence light-emission layers in the uppermost stack unit is a blue light-emission layer.

3. The light-emitting diode of claim 1,
wherein two or more light-emission layers among the light-emission layers included in the uppermost stack unit comprise a thermally activated delayed fluorescence light-emission layer.

4. The light-emitting diode of claim 1,
wherein the thermally activated delayed fluorescence light-emission layer comprises a first host, a second host, a phosphorescence sensitizer, and a thermally activated delayed fluorescence emitter.

5. The light-emitting diode of claim 4,
wherein the first host is a hole transport host, and
wherein the second host is an electron transport host.

6. The light-emitting diode of claim 5,
wherein the thermally activated delayed fluorescence light-emission layer comprises the hole transport host in an amount of 30 to 80 parts by weight, the electron transport host in an amount of 20 to 60 parts by weight, the phosphorescence sensitizer in an amount of 10 to 20 parts by weight and the thermally activated delayed fluorescence emitter in an amount of 0.5 to 3 parts by weight with respect to 100 parts by weight of the light-emission layer.

7. The light-emitting diode of claim 5,
wherein the hole transport host comprises a compound represented by Formula H-1, a compound represented by Formula H-2, or a combination thereof, and
wherein the electron transport host comprises a compound represented by Formula ETH-1: 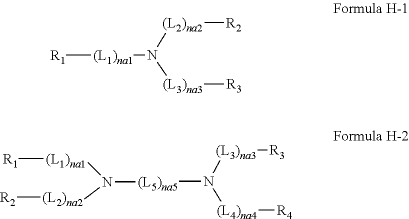
wherein in Formula H-1 and Formula H-2:
the L₁ through L₅ each independently is a direct linkage, a substituted or unsubstituted arylene group having 6 to 30 ring-forming carbons, or a substituted or unsubstituted heteroarylene group having 2 to 30 ring-forming carbons;
the na1 through na4 each independently is an integer greater than or equal to 0 and smaller than or equal to 5;
the na5 is an integer greater than or equal to 1 and smaller than or equal to 10;
the R₁ through R₄ each independently hydrogen,
deuterium, a halogen, a substituted or unsubstituted alkyl group having 1 to 20 carbons, a cycloalkyl group having 3 to 10 ring-forming carbons, a substituted or unsubstituted heterocycloalkyl group having 1 to 10 ring-forming carbons, a substituted or unsubstituted cycloalkenyl group having 3 to 10 ring-forming carbons, a substituted or unsubstituted heterocycloalkenyl group having 1 to 10 ring-forming carbons, a substituted or unsubstituted aryl group having 6 to 60 ring-forming carbons, a substituted or unsubstituted aryloxy group having 6 to 60 carbons, a substituted or unsubstituted arylthio group having 6 to 60 carbons, or a substituted or unsubstituted heteroaryl group having 1 to 60 ring-forming carbons; and
the R₁ and R₂ are optionally connected to each other through a single bond, one or both of the R₁ and R₂ are connected to one or both of the R₃ and R₄ through a single bond, and 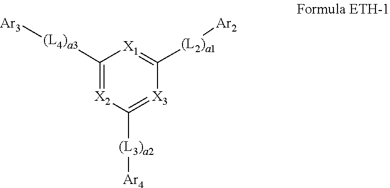
wherein in Formula ETH-1:
X₁ is N or CR₉, X₂ is N or CR₁₀, X₃ is N or CR₁₁, and at least one of X₁ through X₃ is N;
the R₉ through R₁₁ each independently is hydrogen, deuterium, a halogen, a hydroxyl group, a cyano group, a nitro group, a substituted or unsubstituted alkyl group having 1 to 20 carbons, a substituted or unsubstituted alkenyl group having 2 to 20 carbons, a substituted or unsubstituted alkoxy group having 1 to 20 carbons, a substituted or unsubstituted alkynyl group having 2 to 20 carbons, a substituted or unsubstituted aryl group having 6 to 50 ring-forming carbons, or a substituted or unsubstituted heteroaryl group having 2 to 50 ring-forming carbons;
the L₂ through L₄ each independently is a direct linkage, a substituted or unsubstituted arylene group having 6 to 30 ring-forming carbons, or a substituted or unsubstituted heteroarylene group having 2 to 30 ring-forming carbons;
the a1 through a3 each independently is an integer greater than or equal to 0 and smaller than or equal to 10, and when the a₁ through a₃ each is an integer greater than or equal to 2, L₂ through L₄ each independently is a substituted or unsubstituted arylene group having 6 to 30 ring-forming carbons, or a substituted or unsubstituted heteroarylene group having 2 to 30 ring-forming carbons; and
the Ar₂ through Ar₄ each independently is hydrogen, deuterium, a substituted or unsubstituted alkyl group having 1 to 20 carbons, a substituted or unsubstituted aryl group having 6 to 30 ring-forming carbons, and a substituted or unsubstituted heteroaryl group having 2 to 30 ring-forming carbons.

8. The light-emitting diode of claim 4,
wherein the phosphorescence sensitizer comprises a compound represented by Formula P: 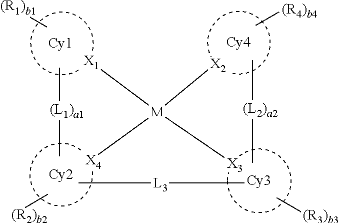
wherein in Formula P:
the Mis platinum (Pt), palladium (Pd), copper (Cu), silver (Ag), gold (Au), rhodium (Rh), iridium (Ir), ruthenium (Ru) or osmium (Os),
the X₁ through X₄ each independently is a carbon (C) or a nitrogen (N);
the rings Cy₁ through Cy₄ each independently is a substituted or unsubstituted carbocyclic ring having 5 to 60 carbons, or a substituted or unsubstituted heterocyclic ring having 3 to 60 carbons;
the L₁ through L₃ each independently is a direct linkage, *—O—*′, *—S—*′, *C(R₅)(R₆)—*′, *—C(R₅)═*′, *═C(R₅)—*′, *—C(R₅)—C(R₆)—*′, *—C(═O)—*′, *—C(═S)—*′, *—C═C—*′, *—B(R₅)—*, *—N(R₅)—*′, *—P(R₅)—*, *—Si(R₅)(R₆)—*′, *—P(R₅)(R₆)—*′ or *—Ge(R₅)(R₆)—*′;
the a₁ and a₂ each independently is an integer greater than or equal to 0 and smaller than or equal to 3, when a₁ is 0, Cy₁ and Cy₂ are not connected to each other through (L₁)a1, when a₁ is 2 or 3, a plurality of L₁ are identical to or different from one another, when a₂ is 0, Cy₃ and Cy₄ are not connected to each other through (L₃)a2, and when a2 is 2 or 3, a plurality of L₃ are identical to or different from one another;
the R₁ through R₄ each independently are hydrogen, deuterium, a halogen, a hydroxyl group, a cyano group, a nitro group, an alkyl group substituted or unsubstituted with at least one R₁₀ₐ and having 1 to 60 carbons, an alkenyl group substituted or unsubstituted with at least one R₁₀ₐ and having 2 to 60 carbons, an alkynyl group substituted or unsubstituted with at least one R₁₀ₐ and having 2 to 60 carbons, an alkoxy group substituted or unsubstituted with at least one R₁₀ₐ and having 1 to 60 carbons, a carbocyclic ring substituted or unsubstituted with at least one R₁₀ₐ and having 3 to 60 carbons, a heterocyclic ring substituted or unsubstituted with at least one R₁₀ₐ and having 3 to 60 carbons, an aryloxy group substituted or unsubstituted with at least one R₁₀ₐ and having 6 to 60 carbons, an arylthio group substituted or unsubstituted with at least one R₁₀ₐ and having 6 to 60 carbons, an arylalkyl group substituted or unsubstituted with at least one R₁₀ₐ and having 7 to 60 carbons, a heteroarylalkyl group substituted or unsubstituted with at least one R₁₀ₐ and having 3 to 60 carbons, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁) or —P(═O)(Q₁)(Q₂);
the b1 through b4 each independently is an integer greater than or equal to 0 and smaller than or equal to 10,
the R₁ through R₄ optionally are connected to each other to form a structure selected from a carbocyclic ring having 3 to 20 carbons connected to one another and a heterocyclic ring having 1 to 20 carbons;
the R₁₀ₐ each independently is a deuterium, a halogen, a hydroxyl group, a cyano group, a nitro group, a carbocyclic ring having 3 to 60 ring-forming carbons, a heterocyclic ring having 2 to 60 ring-forming carbons, an aryloxy group having 6 to 60 carbons, an arylthio group having 6 to 60 carbons, an arylalkyl group having 7 to 60 carbons, a heteroarylalkyl group having 3 to 60 ring-forming carbons, a substituted or unsubstituted alkyl group having 1 to 60 carbons, alkenyl group having 2 to 60 carbons, alkynyl group having 2 to 60 carbons, alkoxy group having 1 to 60 carbons, carbocyclic ring having 3 to 60 ring-forming carbons, heterocyclic ring having 2 to 60 ring-forming carbons, aryloxy group having 6 to 60 carbons, arylthio group having 6 to 60 carbons, arylalkyl group having 7 to 60 carbons, or heteroarylalkyl group having 3 to 60 carbons with —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), or —P(═O)(Q₁₁)(Q₁₂); and
the Q₁ through Q₃ and Q₁₁ through Q₁₃ are each independently a substituted or unsubstituted alkyl group having 1 to 60 carbons, an alkenyl group having 2 to 60 carbons, an alkynyl group having 2 to 60 carbons, an alkoxy group having 1 to 60 carbons, a carbocyclic ring having 3 to 60 ring-forming carbons, or a heterocyclic ring having 1 to 60 ring-forming carbons, wherein each of the foregoing is optionally substituted with hydrogen, deuterium, a halogen, a hydroxyl group, a cyano group, a nitro group, an alkyl group having 1 to 60 carbons, an alkoxy group having 1 to 60 carbons, a phenyl group, a biphenyl group, or a combination thereof.

9. The light-emitting diode of claim 4,
wherein the thermally activated delayed fluorescence emitter comprises a compound represented by Formula F-a: 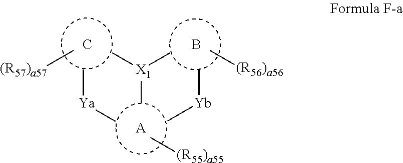
wherein in Formula F-a:
the ring A through ring C are each independently a substituted or unsubstituted aromatic hydrocarbon ring having 6 to 60 ring-forming carbons or a substituted or unsubstituted aromatic heterocyclic ring having 2 to 60 ring-forming carbons;
the Yₐ and Yb are each independently O, S, Se, CR₅₈R₅₉, N—R₆₀, or SiR₆₁R₆₂;
the X₁ is B, P, or P—O;
the R₅₅ through R₆₂ are each independently hydrogen, deuterium, a halogen, a cyano group, a nitro group, an amino group, a substituted or unsubstituted alkyl group having 1 to 30 carbons, a substituted or unsubstituted aryl group having 6 to 60 ring-forming carbons, a substituted or unsubstituted arylamino group, a substituted or unsubstituted cycloalkyl group having 3 to 30 ring-forming carbons, a substituted or unsubstituted heteroaryl group having 2 to 60 ring-forming carbons, a substituted or unsubstituted alkoxy group having 1 to 30 carbons, a substituted or unsubstituted aryloxy group having 6 to 30 carbons, a substituted or unsubstituted arylthio group having 6 to 30 carbons, a substituted or unsubstituted arylamine group having 5 to 30 carbons, a substituted or unsubstituted alkylsilyl group having 1 to 30 carbons, or a substituted or unsubstituted arylsilyl group having 5 to 30 carbons; and
the a₅₅ through a₅₇ are each independently an integer greater than or equal to 0 and smaller than or equal to 20.

10. The light-emitting diode of claim 1,
wherein the stack units comprises a first stack unit; and a second stack unit vertically laminated on the first stack unit, and
wherein one or more electric charge generation layers are arranged between the first stack unit and the second stack unit.

11. The light-emitting diode of claim 10,
wherein a plurality of light-emission layers in the first stack unit comprise at least one of a phosphorescence light-emission layer or a fluorescence light-emission layer, and
wherein one or more light-emission layers among a plurality of light-emission layers in the second stack unit are thermally activated delayed fluorescence light-emission layers configured to emit thermally activated delayed fluorescence.

12. The light-emitting diode of claim 11,
wherein a thickness of the second stack unit is thicker than a thickness of the first stack unit by 50 angstrom to 300 angstrom.

13. The light-emitting diode of claim 10,
wherein λₘₐₓ of either a red phosphorescence sensitizer or a green phosphorescence sensitizer, or both of the red phosphorescence sensitizer and the green phosphorescence sensitizer in the second stack unit satisfies Inequality 1 in relation with λₘₐₓ of a phosphorescence dopant comprised in the first stack unit:
$${λ}_{max} of phosphorescence dopant of the first stack unit - {λ}_{max} of phosphorescence sensitizer of the second stack unit > 1 nanometer . \qquad Inequality 1$$

14. The light-emitting diode of claim 11,
wherein a triplet energy T1 of the thermally activated delayed fluorescence emitter in the second stack unit and a triplet energy T1 of each of a red phosphorescence sensitizer, a green, phosphorescence sensitizer and a blue phosphorescence sensitizer of the second stack unit satisfy at least one of Inequality 2-1 through Inequality 2-3:
$$Δ {T}_{R} = T 1 ( Red sensitizer ) - T 1 ( Red thermally activated delayed fluorescence ) > 0.02 electronvolts \qquad Inequality 2 ‐ 1$$
$$Δ {T}_{G} = T 1 ( Green sensitizer ) - T 1 ( Green thermally activated delayed fluorescence ) > 0.02 electronvolts \qquad Inequality 2 ‐ 2$$
$$Δ {T}_{B} = T 1 ( Blue sensitizer ) - T 1 ( Blue thermally activated delayed fluorescence ) > 0.02 electronvolts . \qquad Inequality 2 ‐ 3$$

15. The light-emitting diode of claim 11,
wherein the phosphorescence light-emission layer and the fluorescence light-emission layer comprise a plurality of light-emitting diodes; and a phosphorescence or fluorescence dopant.

16. The light-emitting diode of claim 15,
wherein the phosphorescence or fluorescence dopant is present in an amount of 0.01 to 30 parts by weight with respect to 100 parts by weight of the light-emission layer composition.

17. The light-emitting diode of claim 1,
wherein the stack unit comprises a hole functional layer; a plurality of light-emission layers; and an electron functional layer,
wherein the hole functional layer comprises a hole transport layer, a hole injection layer, a light-emission auxiliary layer, or a combination thereof, and
wherein the electron functional layer comprises an electron transport layer, an electron injection layer, a barrier film layer, a buffer layer, or aa combination thereof.

18. The light-emitting diode of claim 17,
wherein the light-emission auxiliary layer is comprised in a blue light-emission layer.

19. An electronic device comprising:
a first electrode;
a second electrode arranged on the first electrode; and
stack units arranged between the first electrode and the second electrode, vertically laminated to form a plurality of layers, and comprising n light-emission layers on each layer,
wherein one or more light-emission layers among a plurality of light-emission layers in at least an uppermost stack unit among the laminated stack units are thermally activated delayed fluorescence light-emission layers configured to emit thermally activated delayed fluorescence, and
wherein at least one stack unit below the uppermost stack unit comprises a light-emitting diode comprising at least one of a phosphorescence light-emission layer or a fluorescence light-emission layer.

20. The electronic device of claim 19,
wherein the electronic device comprises a display device; a processor configured to control the display device; a memory configured to store data necessary for operation of the display device or the processor; and a power module configured to generate or supply power.
